(19) United States
(12) Patent Application Publication
(10) Pub. No.: US 2020/0295260 A1
(43) Pub. Date: Sep. 17, 2020

(54) CORRELATED ELECTRON SWITCH DEVICE SIDEWALL RESTORATION

(71) Applicant: Arm Limited, Cambridge (GB)

(72) Inventors: Xueming Huang, Cupertino, CA (US); Ming He, San Jose, CA (US); Marinela Barci, Vilvoored (BE); Paul Raymond Besser, Sunnyvale, CA (US); Saurabh Vinayak Suryavanshi, Mountain View, CA (US); Lucian Shifren, San Jose, CA (US)

(21) Appl. No.: 16/850,875

(22) Filed: Apr. 16, 2020

Related U.S. Application Data
(63) Continuation-in-part of application No. 16/748,555, filed on Jan. 21, 2020.
Application No. 16/748,555 is a continuation-in-part of application No. 16/163,190, filed on Oct. 17, 2018.
Application No. 16/163,190 is a continuation-in-part of application No. 16/163,246, filed on Oct. 17, 2018.
Application No. 16/163,246 is a continuation-in-part of application No. 15/933,818, filed on Mar. 23, 2018.

(51) Int. Cl. H01L 45/00

(52) U.S. Cl. CPC H01L 45/1625; H01L 45/145; H01L 45/1616; H01L 45/1675; H01L 45/141

(57) ABSTRACT

Subject matter disclosed herein may relate to fabrication of a correlated electron material (CEM) device. Layers of a CEM to form a correlated electron switch (CES) device may be disposed between layers of electrode material. In an embodiment, one or more techniques may be employed to remove and/or neutralize parasitic features and/or devices introduced during manufacture of the CEM device.

### CROSS-REFERENCE TO RELATED APPLICATIONS

This application is a Continuation-In-Part of U.S. application Ser. No. 16/748,555, titled “ELECTRODE FOR CORRELATED ELECTRON DEVICE,” filed Jan. 21, 2020, a Continuation-In-Part of U.S. application Ser. No. 16/163,190, titled “FORMATION OF CORRELATED ELECTRON MATERIAL (CEM) DEVICES WITH RESTORED SIDEWALL REGIONS,” filed Oct. 17, 2018, a Continuation-In-Part of U.S. application Ser. No. 16/163,246, titled “CORRELATED ELECTRON MATERIAL (CEM) DEVICES WITH CONTACT REGION SIDEWALL INSULATION,” filed Oct. 17, 2018, and a Continuation-In-Part of U.S. application Ser. No. 15/933,818, titled “METHOD FOR FABRICATION OF A CEM DEVICE,” filed Mar. 23, 2018, all of which are assigned to the assignee hereof and are expressly incorporated herein by reference in their entirety.

### BACKGROUND

### Field

This disclosure relates to devices formed from correlated electron material (CEM), and may relate, more particularly, to approaches for fabricating CEM devices, such as may be used in switches, memory circuits, and so forth, which may exhibit desirable impedance switching characteristics.

Information:

Integrated circuit devices, such as electronic switching devices, for example, may be found in numerous types of electronic devices. For example, memory and/or logic devices may incorporate electronic switches suitable for use in computers, digital cameras, smart phones, computing devices, wearable electronic devices, and so forth. Factors that may relate to electronic switching devices, which may be of interest to a designer in considering whether an electronic switching device is suitable for particular applications, may include physical size, storage density, operating voltages, impedance ranges, switching speed, and/or power consumption, for example. Other factors may include, for example, cost and/or ease of manufacture, scalability, and/or reliability.

### BRIEF DESCRIPTION OF THE DRAWINGS

Claimed subject matter is particularly pointed out and distinctly claimed in the concluding portion of the specification. However, both as to organization and/or method of operation, together with objects, features, and/or advantages thereof, it may best be understood by reference to the following detailed description if read with the accompanying drawings in which:

FIG. 1A is an illustration of an embodiment of a current density versus voltage profile of a device formed from a correlated electron material (CEM);

FIG. 1B is an illustration of an embodiment of a switching device comprising a correlated electron material and a schematic diagram of an equivalent circuit of a correlated electron material switch;

FIGS. 2A through 2E are schematic diagrams of a correlated electron material switch device according to embodiments;

FIG. 3 is a cross-section of a switching device formed from a correlated electron material according to an embodiment;

FIGS. 4A through 4D are cross-sectional diagrams illustrating stages in forming a switching device comprising a correlated electron material from deposited layers of material according to an embodiment;

FIGS. 5A through 5H are cross-sectional diagrams illustrating processes in the formation of a switching device formed from a correlated electron material according to an embodiment;

FIG. 6 is a schematic diagram of a circuit comprising one or more layers of CEM disposed between a top electrode and a bottom electrode to provide a switching device according to an embodiment;

FIG. 7 is a flow diagram illustrating a process of fabricating and/or constructing a CEM switching device according to embodiments; and

FIG. 8 is a schematic diagram of a system for manufacture of a device according to an embodiment.

Reference is made in the following detailed description to accompanying drawings, which form a part hereof, wherein like numerals may designate like parts throughout that are corresponding and/or analogous. It will be appreciated that the figures have not necessarily been drawn to scale, such as for simplicity and/or clarity of illustration. For example, dimensions of some aspects may be exaggerated relative to others. Further, it is to be understood that other embodiments may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, etc.), or to a particular claim. It should also be noted that directions and/or references, for example, such as up, down, top, bottom, and so on, may be used to facilitate discussion of drawings and are not intended to restrict application of claimed subject matter. Therefore, the following detailed description is not to be taken to limit claimed subject matter and/or equivalents.

### DETAILED DESCRIPTION

References throughout this specification to one implementation, an implementation, one embodiment, an embodiment, and/or the like indicates that a particular feature, structure, characteristic, and/or the like described in relation to a particular implementation and/or embodiment is included in at least one implementation and/or embodiment of claimed subject matter. Thus, appearances of such phrases, for example, in various places throughout this specification are not necessarily intended to refer to the same implementation and/or embodiment or to any one particular implementation and/or embodiment. Furthermore, it is to be understood that particular features, structures, characteristics, and/or the like described are capable of being combined in various ways in one or more implementations and/or embodiments and, therefore, are within intended claim scope. In general, of course, as has been the case for the specification of a patent application, these and other issues have a potential to vary in a particular context of usage. In other words, throughout the disclosure, particular context of description and/or usage provides helpful guidance regarding reasonable inferences to be drawn; however, likewise, “in this context” in general without further qualification refers to the context of the present disclosure.

Particular aspects of the present disclosure describe methods and/or processes for preparing and/or fabricating correlated electron materials (CEMs) films to form, for example, a correlated electron switch, such as may be utilized to form a correlated electron random access memory (CeRAM), and/or logic devices, for example. Correlated electron materials, which may be utilized in the construction of CeRAM devices and CEM switches, for example, may also comprise a wide range of other electronic circuit types, such as, for example, memory controllers, memory arrays, filter circuits, data converters, optical instruments, phase locked loop circuits, microwave and millimeter wave transceivers, and so forth, although claimed subject matter is not limited in scope in these respects.

In an implementation of a process to form a correlated electron switch, one or more layers of a CEM may be deposited to form a thin film providing a bulk material between metallic and/or electrode layers that may be switchable between impedance states. Formed layers may be further etched to form a structure (e.g., a “pillar” structure) including exposed sidewalls of the thin film CEM formed between the metallic and/or electrode layers. Such exposed sidewalls of the thin film CEM may be affected at least in part by a process to etch the formed layers such that one or more parasitic devices and/or features may be formed which may affect switching behavior of bulk CEM in the formed structure. According to an embodiment, additional processes may be employed to remove and/or neutralize such parasitic devices and/or features formed by an etching process so as to restore and/or improve switching performance of the thin film CEM.

In this context, a CEM switch, for example, may exhibit a substantially rapid conductive-state-to-insulative-state transition, which may be enabled, at least in part, by electron correlations, which modify electrical properties of the material, rather than solid-state structural phase changes, such as in response to a change from a crystalline to an amorphous state, for example. Such solid-state structural phase changes, such as from crystalline to amorphous states, for example, may bring about formation of conductive filaments in certain resistive RAM devices. In one aspect, a substantially rapid conductor-to-insulator transition in a CEM device may occur responsive to a quantum mechanical phenomenon that takes place within a bulk of a material making up such an CEM device, in contrast to melting/solidification and/or localized filament formation, for example, in phase change and certain resistive RAM devices. Such quantum mechanical transitions between relatively conductive and relatively insulative states, and/or between a first impedance state and a second, dissimilar impedance state, for example, in a CEM device may be understood in any one of several aspects. As used herein, the terms “relatively conductive state,” “relatively lower impedance state,” and/or “metal state” may be interchangeable, and/or may, at times, be referred to as a “relatively conductive and/or lower-impedance state.” Likewise, the terms “relatively insulative state” and “relatively higher impedance state” may be used interchangeably herein, and/or may, at times, be referred to as a “relatively insulative and/or higher impedance state.” Further, in a relatively insulative and/or higher-impedance state, a CEM may be characterized by a range of impedances, and in a relatively conductive and/or lower-impedance state, a CEM may be characterized by a second range of impedances.

In an aspect, a quantum mechanical transition of a CEM between a relatively insulative and/or higher impedance state and a relatively conductive and/or lower impedance state, wherein the relatively conductive and/or lower impedance state is substantially dissimilar from the insulative and/or higher impedance state, may be understood in terms of a Mott transition. In accordance with a Mott transition, a material may switch between a relatively insulative and/or higher impedance state and a relatively conductive and/or lower impedance state if a Mott transition condition occurs. Mott criteria may be defined by (n_{c})^{1/3} a≈0.26, wherein n_{c} denotes a concentration of electrons, and wherein “a” denotes the Bohr radius. If a threshold charge density is achieved, such that Mott criteria is met, a Mott transition may be believed to occur. Responsive to occurrence of a Mott transition, a state of a CEM device may change between a relatively higher resistance and/or higher capacitance state (e.g., a higher-impedance and/or insulative state) and a relatively lower resistance and/or lower capacitance state (e.g., a lower-impedance and/or conductive state) that is substantially dissimilar from the higher resistance and/or higher capacitance state.

In another aspect, a Mott transition may be controlled, at least in part, by a localization of electrons. If carriers, such as electrons, for example, are localized, a strong coulomb interaction between carriers may split bands of the CEM (e.g., split conductive and valence bands) to bring about a relatively insulative (relatively higher impedance) state. If electrons are no longer localized, a weak coulomb interaction may dominate, which may give rise to a removal of band splitting.

Further, in an embodiment, switching from a relatively insulative and/or higher impedance state to a substantially dissimilar and relatively conductive and/or lower impedance state may enable a change in capacitance in addition to a change in resistance. For example, a CEM device may exhibit a variable resistance together with a property of a variable capacitance. In other words, impedance characteristics of a CEM device may include both resistive and capacitive components. For example, in a metallic state, a CEM device may comprise a relatively low electric field that may approach zero, and thus may exhibit a substantially low capacitance, which may likewise approach zero.

Similarly, in a relatively insulative and/or higher impedance state, which may be brought about by a higher density of bound or correlated electrons, an external electric field may be capable of penetrating a CEM and, therefore, such a CEM may exhibit higher capacitance based, at least in part, on additional charges stored within the CEM. Thus, for example, a transition from a relatively insulative and/or higher impedance state to a substantially dissimilar and relatively conductive and/or lower impedance state in a CEM device may result in changes in both resistance and capacitance, at least in particular embodiments. Such a transition may bring about additional measurable phenomena, and claimed subject matter is not limited in this respect.

In an embodiment, a device formed from a CEM may exhibit switching of impedance states responsive to a Mott-transition occurring in a majority of bulk volume of CEM forming a CEM-based device. In an embodiment, a CEM may form a “bulk switch.” As used herein, the term “bulk switch” refers to at least a substantial volume of a CEM switching a device's impedance state, such as between a low impedance and/or conductive state and a high impedance and/or insulative state such as responsive to a Mott-transition. For example, in an embodiment, substantially all of a portion of bulk CEM of a device may switch between a relatively insulative and/or higher impedance state and a relatively conductive and/or lower impedance state (e.g., a “metal” or “metallic state”) responsive to a Mott transition.

In particular implementations, a bulk material comprising a CEM may comprise one or more “d block” elements or compounds of “d block” elements, which correspond to transition metals transition metal oxides (TMOs). A CEM may also comprise a post transition metal, which may correspond with post transition metal oxides (PTMOs) or post transition metal chalcogenides (PTMCs), for example. For example, a bulk material forming a CEM device may comprise a CEM compound of a PTMO and/or PTMC formed from a Period 6 post transition metal (e.g., Bi, Pb, Hg and/or Td) combined with a PTMO and/or PTMC formed from a Period 5 post transition metal (e.g., Cd, In, Sn and/or Sb). In another particular implementation, a bulk material forming a CEM device may comprise a CEM compound of a PTMO and/or PTMC formed from a Period 6 post transition metal combined with a PTMO and/or PTMC formed from a Period 4 post transition metal (e.g., Zn and/or Ga). In another particular implementation, a bulk material forming a CEM device may comprise a CEM compound of a PTMO and/or PTMC formed from a Period 6 post transition metal combined with a PTMO and/or PTMC formed from a Period 5 post transition metal, and further combined with a PTMO and/or PTMC formed from PTMO and/or PTMC formed from a Period 4 post transition metal.

CEM devices may also be implemented utilizing one or more “f block” elements or compounds of “f block” elements. A CEM may comprise one or more rare earth elements, oxides of rare earth elements, oxides comprising one or more rare earth transition metals, perovskites, yttrium, and/or ytterbium, or any other compounds comprising metals from the lanthanide or actinide series of the periodic table of the elements, for example, and claimed subject matter is not limited in scope in this respect.

A bulk CEM may additionally comprise a dopant, such as a carbon-containing dopant and/or a nitrogen-containing dopant, wherein an atomic concentration of a resulting ligand (e.g., of carbon or nitrogen) in a CEM may be controlled in part to be a particular predefined atomic concentration (e.g., between about 1.0 parts per million (ppm) to about 20.0%). As referred to herein, the term “atomic concentration” means a ratio of a number of dopant atoms to the total number of atoms in a material.

In this context, a “ligand” as referred to herein means an ion or molecule attached to a metal atom by coordinate bonding. In the case of a metal oxide or metal chalcogenide, for example, such a ligand may comprise ions of oxygen and/or chalcogenide bonding to a metal ion. In a process to form a CEM (e.g., to enhance switching properties of a metal oxide or metal chalcogenide), a dopant may be applied to a host material (e.g., a metal oxide). In this context, a “dopant” or “doping agent” as referred to herein means an impurity that is introduced into a host material to alter one or more original electrical and/or optical properties of the host material. In one embodiment of a metal oxide host material, oxygen may serve as an “intrinsic ligand.” In a particular implementation of a process to form a bulk material having desired properties (e.g., a CEM), application of a dopant may introduce an “extrinsic ligand” such as carbon, nitrogen and/or CO capable of binding with molecules of the host material to substitute for intrinsic ligands if oxygen vacancies occur in molecules of a host material (e.g., host material comprising a bulk TMO, PTMO and/or PTMC). In this context, an extrinsic ligand, as a ligand supplied by an applied dopant, may comprise a “substitutional ligand” that binds to an oxygen vacancy of a metal ion.

As the term is used herein, a “d block” element means an element comprising scandium (Sc), titanium (Ti), vanadium (V), chromium (Cr), manganese (Mn), iron (Fe), cobalt (Co), nickel (Ni), copper (Cu), zinc (Zn), yttrium (Y), zirconium (Zr), niobium (Nb), molybdenum (Mo), technetium (Tc), ruthenium (Ru), rhodium (Rh), palladium (Pd), silver (Ag), cadmium (Cd), hafnium (Hf), tantalum (Ta), tungsten (W), rhenium (Re), osmium (Os), iridium (Ir), platinum (Pt), gold (Au), mercury (Hg), rutherfordium (Rf), dubnium (Db), seaborgium (Sg), bohrium (Bh), hassium (Hs), meitnerium (Mt), darmstadtium (Ds), roentgenium (Rg) or copernicium (Cn), or any combination thereof. A CEM formed from or comprising an “f block” element of the periodic table of elements means a CEM comprising a metal or metal oxide, wherein the metal is from the f block of the periodic table of elements, which may include lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), actinium (Ac), thorium (Th), protactinium (Pa), uranium (U), neptunium (Np), plutonium (Pu), americium (Am), berkelium (Bk), californium (Cf), einsteinium (Es), fermium (Fm), mendelevium (Md), nobelium (No) or lawrencium (Lr), or any combination thereof.

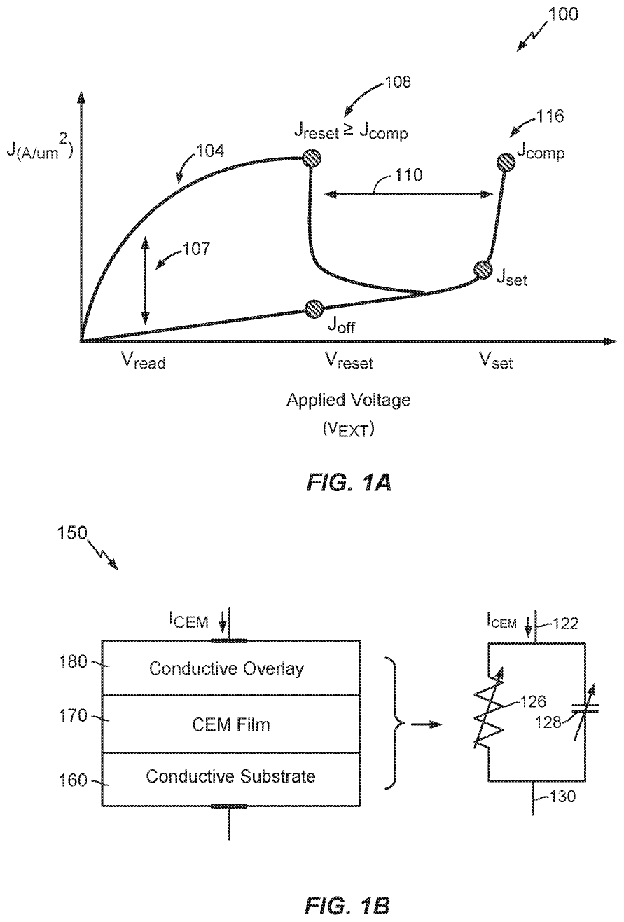

FIG. 1A is an illustration of an embodiment 100 of a current density (J) in a material versus an applied voltage (VExT) for a device formed from a CEM. At least partially responsive to a voltage applied to terminals of a CEM device, for example, during a “write operation,” such a CEM device may be placed into a relatively low-impedance and/or conductive state, or a relatively high-impedance and/or insulative state. For example, application of a voltage Vₛₑₜ and a current density Jₛₑₜ may enable a transition of a CEM device to a relatively low-impedance and/or conductive state. Conversely, application of a voltage Vᵣₑₛₑₜ and a current density Jᵣₑₛₑₜ may enable a transition of a CEM device to a relatively high-impedance and/or insulative state. As shown in FIG. 1A, reference designator 110 may illustrate a voltage range that may separate Vₛₑₜ from Vᵣₑₛₑₜ. Following placement of a CEM device into a high-impedance state and/or insulative or into a low-impedance and/or conductive state, a particular state of such a CEM device may be detectable by application of a voltage Vread (e.g., during a read operation) and detection of a current and/or current density at terminals of the CEM device (e.g., utilizing read window 107).

According to an embodiment, a CEM device characterized in FIG. 1A may comprise any one of several metal oxides, such as, for example, perovskites, Mott insulators, charge exchange insulators, and Anderson disorder insulators, as well as any one of several compounds and/or materials comprising a d block element, f block element and/or post transition metal. In one aspect, a CEM device according to FIG. 1A may comprise other types of metal oxide switching materials, though it should be understood that these are exemplary only and are not intended to limit claimed subject matter. Nickel oxide (NiO) is disclosed as one particular example metal oxide material, although claimed subject matter is not limited to any particular metal oxide material. While specific examples using NiO as a CEM are used to illustrate particular techniques, these techniques may be applicable to CEM formed from other TMOs, as well as CEM formed from PTMOs and PTMCs. NiO materials discussed herein may be doped with substitutional ligands, such as carbon-containing materials (e.g., carbon, carbon monoxide carbonyl (CO)₄), or nitrogen-containing materials, such as ammonia (NH₃), for example, which may establish and/or stabilize material properties and/or enable a p-type operation in which a CEM may be more conductive while placed into a low-impedance and/or conductive state. Thus, in another particular example, NiO doped with substitutional ligands may be expressed as NiO:Lₓ, where Lₓ may indicate a ligand element and/or compound and x may indicate a number of units of the ligand for one unit of NiO. A value of x may be determined for a specific ligand and/or a specific combination of ligands with NiO or with another transition metal compound by balancing valences. Other dopant ligands, which may enable or increase conductivity in a metal oxide in addition to carbonyl may include, for example: nitrosyl (NO), an isocyanide (RNC wherein R is H, C₁-C₆ alkyl or C₆-C₁₀ aryl), a phosphine (R₃P wherein R is C₁-C₆ alkyl or C₆-C₁₀ aryl) for example, triphenylphosphine (PPh₃), an alkyne (e.g., ethyne) or phenanthroline (C₁₂H₈N₂), bipyridine (C₁₀H₈N₂), ethylenediamine (C₂H₄(NH₂)₂), acetonitrile (CH₃CN), fluoride (F), chloride (Cl), bromide (Br), cyanide (CN), sulfur (S), carbon (C), and others.

In this context, a “p-type” doped CEM as referred to herein means a first type of CEM comprising a particular molecular dopant that exhibits increased electrical conductivity, relative to an undoped CEM, while such CEM is operated in a relatively low-impedance and/or conductive state. Introduction of a substitutional ligand, such as CO and/or NH₃ by way of application of a dopant, may operate to enhance a p-type nature of a NiO-based CEM, for example. Accordingly, an attribute of p-type operation of a bulk CEM may include, at least in particular embodiments, an ability to tailor and/or customize electrical conductivity of a CEM at least in part by controlling an atomic concentration of a p-type dopant in a CEM. In particular embodiments, an increased atomic concentration of a p-type ligand may enable increased electrical conductivity of a CEM, although claimed subject matter is not limited in this respect. In particular embodiments, changes in atomic concentration and/or atomic percentage of p-type ligand in a CEM may be observed in characteristics of region 104 of FIG. 1A, as described herein, wherein an increase in p-type ligand may bring about a steeper (e.g., more positive) slope of region 104 to indicate higher conductivity.

In another embodiment, a CEM device represented by a current density versus voltage profile of FIG. 1A, may comprise other TMO, PTMO and/or PTMC materials, such as carbon-containing ligands or nitrogen-containing ligands, though it should be understood that these are exemplary only and are not intended to limit claimed subject matter. NiO, for example, may be doped with substitutional nitrogen-containing ligands, which may stabilize switching properties in a manner similar to stabilization switching properties responsive to application of a carbon-containing dopant species (e.g., carbonyl). In particular, NiO materials disclosed herein may include nitrogen-containing molecules of the form CₓH_{y}N_{z} (wherein x≥0, y≥0, z≥0, and wherein at least x, y, or z comprise values >0) such as ammonia (NH₃), cyano (CN⁻), azide ion (N₃⁻) ethylene diamine (C₂H₈N₂), phen(1,10-phenanthroline) (C₁₂H₈N₂), 2,2′bipyridine (C₁₀,H₈N₂), ethylenediamine ((C₂H₄(NH₂)₂), pyridine (C₅H₅N), acetonitrile (CH₃CN), and cyanosulfanides such as thiocyanate (NCS⁻), for example. NiO switching materials disclosed herein may include members of an oxynitride family (NₓO_{y}, wherein x and y comprise whole numbers, and wherein x≥0 and y≥0 and at least x or y comprise values >0), which may include, for example, nitric oxide (NO), nitrous oxide (N₂O), nitrogen dioxide (NO₂), or precursors with an NO₃⁻ ligand.

In accordance with FIG. 1A, if sufficient bias voltage is applied (e.g., exceeding a band-splitting potential) and an aforementioned Mott condition is satisfied (e.g., injected electron holes are of a population comparable to a population of electrons in a switching region, for example), a CEM device may switch between a relatively low-impedance and/or conductive state and a relatively high-impedance and/or insulative state, for example, responsive to a Mott transition. This may correspond to point 108 of the voltage versus current density profile of FIG. 1A. At, or suitably near this point, electrons may no longer be screened and become localized near a metal ion. This correlation may result in a strong electron-to-electron interaction potential, which may operate to split bands to form a relatively high-impedance and/or insulative material. If a CEM device comprises a relatively high-impedance and/or insulative state, current may be generated by transportation of electron holes. Consequently, if a threshold voltage is applied across terminals of a CEM device, electrons may be injected into a metal-insulator-metal (MIM) diode over a potential barrier of such an MIM device. In certain embodiments, injection of a threshold current of electrons, at a threshold potential applied across terminals of a CEM device, may perform a “set” operation, which may place such a CEM device into a low-impedance and/or conductive state. In a low-impedance and/or conductive state, an increase in electrons may screen incoming electrons and remove a localization of electrons, which may operate to collapse the band-splitting potential, thereby giving rise to a low-impedance and/or conductive state.

In accordance with particular embodiments, current and/or current density in a CEM device may be controlled by an externally applied “compliance” condition, which may be determined at least partially on the basis of an applied external current, which may be limited during a write operation, for example, to place the CEM device into a relatively low-impedance and/or conductive state. This externally applied compliance current may, in some embodiments, also determine a condition of a current density in CEM for a subsequent reset operation to place the CEM device into a relatively high-impedance and/or insulative state. As shown in the particular implementation of FIG. 1A, a voltage Vₛₑₜ may be applied during a write operation to give rise to a current density J_{comp}, such as at point 116, to place the CEM device into a relatively low-impedance and/or conductive state, which may determine a compliance condition for placing the CEM device into a relatively high-impedance and/or insulative state in a subsequent write operation. As shown in FIG. 1A, a CEM device may be subsequently placed into a high-impedance and/or insulative state by application of an externally applied voltage (Vᵣₑₛₑₜ), which may give rise to a current density Jᵣₑₛₑₜ≥J_{comp} at a voltage referenced by 108 in FIG. 1A.

In embodiments, a compliance condition may determine a number of electrons in a CEM device that may be “captured” by holes for a Mott transition. In other words, a current and/or current density applied in a write operation to place a CEM device into a relatively low-impedance and/or conductive memory state may determine a number of holes to be injected to the CEM device for subsequently transitioning the CEM device to a relatively high-impedance and/or insulative state.

As pointed out above, a reset condition may occur responsive to a Mott transition at point 108. As pointed out above, such a Mott transition may give rise to a condition in a CEM device in which a concentration of electrons n approximately equals, or becomes at least comparable to, a concentration of electron holes p. This condition may be modeled according to expression (1) as follows:

$$\begin{matrix}{λ}_{T F} {n}^{\frac{1}{3}} = C ∼ 0.26 & ( 1 ) \\ n = {( \frac{C}{{λ}_{T F}} )}^{3} & \end{matrix}$$

In expression (1), λ_{TF} corresponds to a Thomas Fermi screening length, and C is a constant.

According to an embodiment, a current and/or current density in region 104 of the voltage versus current density profile shown in FIG. 1A may occur responsive to injection of holes from a voltage signal applied across terminals of a CEM device, which may correspond to vp-type operation of the CEM device. Here, injection of holes may meet a Mott transition criterion for a low-impedance and/or conductive state to high-impedance and/or insulative state transition at current I_{MI} as a threshold voltage V_{MI} is applied across terminals of a CEM device. This may be modeled according to expression (2) as follows:

$$\begin{matrix}{I}_{M I} ( {V}_{MI} ) = \frac{dQ ( {V}_{MI} )}{d t} \approx \frac{Q ( {V}_{MI} )}{t} & ( 2 ) \\ Q ( {V}_{MI} ) = qn ( {V}_{MI} ) & \end{matrix}$$

In expression (2), Q(V_{MI}) corresponds to a charged injected (holes or electrons) and may, at least in part, be a function of an applied voltage. Injection of electrons and/or holes to enable a Mott transition may occur between bands and responsive to threshold voltage V_{MI}, and threshold current I_{MI}. By equating electron concentration n with a charge concentration to bring about a Mott transition by holes injected by I_{MI} in expression (2) according to expression (1), a dependency of such a threshold voltage V_{MI} on Thomas Fermi screening length λ_{TF} may be modeled according to expression (3), as follows:

$$\begin{matrix}{I}_{M I} ( {V}_{M I} ) = \frac{Q ( {V}_{M I} )}{t} = \frac{q n ( {V}_{M I} )}{t} = \frac{q}{t} {( \frac{C}{{λ}_{T F}} )}^{3} & ( 3 ) \\ {J}_{reset} ( {V}_{M I} ) = {J}_{M I} ( {V}_{M I} ) = \frac{{I}_{M I} ( {V}_{M I} )}{{A}_{CEM}} = \frac{q}{{A}_{CEM} t} {( \frac{C}{{λ}_{T F}} )}^{3} & \end{matrix}$$

In expression (3), A_{CEm} is a cross-sectional area of a CEM device; and expression (3) may represent a current density through the CEM device to be applied to the CEM device at a threshold voltage V_{MI}, which may place the CEM device into a relatively high-impedance and/or insulative state.

According to an embodiment, a CEM device, which may be utilized to form a CEM switch, a CERAM memory device, and/or a variety of other electronic devices comprising one or more correlated electron materials, may be placed into a relatively low-impedance and/or conductive memory state, such as by transitioning from a relatively high-impedance and/or insulative state, for example, via injection of a sufficient quantity of electrons to satisfy a Mott transition criteria. In transitioning a CEM device to a relatively low-impedance and/or conductive state, if enough electrons are injected and a potential across terminals of such a CEM device overcomes a threshold switching potential (e.g., Vₛₑₜ), injected electrons may begin to screen. As previously mentioned, screening may operate to unlocalize double-occupied electrons to collapse band-splitting potential, thereby bringing about a relatively low-impedance and/or conductive state.

In particular embodiments, changes in impedance states of a CEM device may be brought about by “back-donation” of electrons of compounds comprising NixO_{y}(wherein the subscripts “x” and “y” comprise whole numbers). As the term is used herein, “back-donation” refers to a supplying of one or more electrons (e.g., increased electron density) to a metal, metal oxide or metal chalcogenide, or any combination thereof (e.g., to an atomic orbital of a metal), by an adjacent molecule of a lattice structure, such as a ligand and/or dopant. Back-donation also refers to a reversible donation of electrons (e.g., an increase electron density) from a metal atom to an unoccupied π-antibonding orbital on a ligand and/or dopant. Back-donation may enable a metal, metal compound or metal oxide, or a combination thereof, to maintain an ionization state that is favorable to electrical conduction under an influence of an applied voltage. In certain embodiments, back-donation in a CEM, for example, may occur responsive to application of carbon-containing dopants, such as carbonyl (CO)₄, or a nitrogen-containing dopant species, such as ammonia (NH₃), ethylene diamine (C₂H₈N₂), or members of an oxynitride family (NₓO_{y}), for example, which may enable a CEM to exhibit a property in which electrons are controllably, and reversibly, “donated” to a conduction band of a metal or metal oxide, such as nickel or nickel oxide, for example, during operation of a device or circuit comprising a CEM. Back donation may be reversed, for example, in a nickel oxide material (e.g., NiO:CO or NiO:NH₃), thereby enabling such a nickel oxide material to switch to exhibiting a substantially dissimilar impedance property, such as a high-impedance and/or insulative property, during device operation.

Thus, in this context, an electron back-donating material refers to a material that exhibits an impedance switching property, such as switching from a first impedance state to a substantially dissimilar second impedance state (e.g., from a relatively low impedance state to a relatively high impedance state, or vice versa) responsive, at least in part, to an applied voltage to control donation of electrons, and reversal of the electron donation, to and from a conduction band of a CEM.

In some embodiments, by way of back-donation, a CEM switch comprising a transition metal (e.g., in a transition metal compound and/or a transition metal oxide) or post transition meta (e.g., in a post transition metal compound, post transition metal oxide and/or a post transition metal chalcogenide), may exhibit low-impedance and/or conductive properties if such a transition metal, such as nickel, for example, is placed into an oxidation state of 2+(e.g., Ni²⁺ in a material, such as NiO:CO or NiO:NH₃). Conversely, electron back-donation in a CEM comprising a transition metal, such as in the particular example of nickel, may be reversed by placing such a transition metal into an oxidation state of 1+ or 3+. Accordingly, during operation of a nickel-based CEM device, back-donation may result in “disproportionation,” which may comprise substantially simultaneous oxidation and reduction reactions, substantially in accordance with expression (4), below:

2Ni²⁺→Ni¹⁺+Ni³⁺ (4)

Such disproportionation, in the specific example of expression (4), refers to formation of nickel ions as Ni¹⁺+Ni³⁺, which may bring about, for example, a relatively high-impedance and/or insulative state during operation of a CEM device. In an embodiment, application of a dopant such as a carbon-containing ligand, carbonyl (CO) and/or a nitrogen-containing ligand, such as an ammonia molecule (NH₃), may permit sharing of electrons during operation of a nickel-based CEM device so as to give rise to the disproportionation reaction of expression (4), and its reversal, substantially in accordance with expression (5), below:

Ni¹⁺+Ni³⁺→2Ni²⁺ (5)

As previously mentioned, reversal of a disproportionation reaction, as shown in expression (5), may permit a nickel-based CEM to return to a relatively low-impedance and/or conductive state.

In embodiments, depending on a molecular concentration of NiO:CO or NiO:NH₃, for example, which may vary from values approximately in the range of an molecular concentration of about 0.1% to about 20.0%, magnitudes of Vₛₑₜ and Vₛₑₜ (|Vₛₑₜ| and |Vᵣₑₛₑₜ|, respectively), as shown in FIG. 1A, may vary approximately in the range of about 0.1 V to about 10.0 V subject to the condition that |Vₛₑₜ|≥|Vᵣₑₛₑₜ|. For example, in one possible embodiment, |Vᵣₑₛₑₜ| may occur at a voltage approximately in a range of about 0.1 V to about 1.0 V, and |Vₛₑₜ| may occur at a voltage approximately in a range of about 1.0 V to about 2.0 V, for example. It should be noted, however, that variations in magnitudes of Vₛₑₜ and Vᵣₑₛₑₜ may occur based, at least in part, on a variety of factors, such as atomic concentration of an electron back-donating material, such as NiO:CO or NiO:NH₃ and other materials present in a CEM device, as well as other process variations, and that claimed subject matter is not limited in this respect.

FIG. 1B is an illustration of an embodiment 150 of a switching device comprising a CEM and a schematic diagram of an equivalent circuit of a CEM switch. As previously mentioned, a correlated electron device, such as a CEM switch, a CERAM array, or other type of device utilizing one or more CEMs may comprise a variable or complex impedance device that may exhibit characteristics of both variable resistance and variable capacitance. In other words, impedance characteristics for a CEM variable impedance device, such as a device comprising conductive substrate 160, CEM film 170, and conductive overlay 180, may depend at least in part on resistance and capacitance characteristics of such a device measured across device terminals 122 and 130. In an embodiment, an equivalent circuit for a variable impedance device may comprise a variable resistor, such as variable resistor 126, in parallel with a variable capacitor, such as variable capacitor 128. Of course, although variable resistor 126 and variable capacitor 128 are depicted in FIG. 1B as comprising discrete components, a variable impedance device, such as a device of embodiment 150, may comprise a substantially homogenous CEM film and/or bulk CEM film, and claimed subject matter is not limited in this respect.

Table 1 below depicts characteristics of an example variable impedance device, such as a device of embodiment 150.

TABLE 1
Correlated Electron Switch Truth Table

| Resistance | Capacitance | Impedance |
|---|---|---|
| R_{high}(V_{applied}) | C_{high}(V_{applied}) | Z_{high}(V_{applied}) |
| R_{low}(V_{applied}) | C_{low}(V_{applied})~0 | Z_{low}(V_{applied}) |

In an embodiment, Table 1 shows that a resistance of a variable impedance device, such as a device of embodiment 150, may transition between a lower resistance state, which, in an example embodiment, may comprise approximately zero (or negligible) resistance state, and a higher resistance that is a function, at least in part, of a voltage applied across such a device. Similarly, Table 1 shows that a capacitance of a variable impedance device, such as a device of embodiment 150, may transition between a lower capacitance state which, in an example embodiment, may comprise approximately zero (or negligible) capacitance, and a higher capacitance state that is a function, at least in part, of a voltage applied across such a device. Accordingly, a device of embodiment 150 may comprise a switching device capable of switching between and a low impedance and/or conductive state and a substantially dissimilar, high-impedance and/or insulative state as a function at least partially dependent on a voltage applied across such a device. In an embodiment, an impedance of a device of embodiment 150 exhibited at a low-impedance and/or conductive state may be approximately in the range of 10⁻¹ to 10⁻⁵ that of an impedance exhibited in a high-impedance and/or insulative state. In other embodiments, an impedance exhibited at a low-impedance and/or conductive state may be approximately in the range of 0.1 to 0.2 that of an impedance exhibited in a high-impedance and/or insulative state, for example. It should be noted, however, that claimed subject matter is not limited to any particular impedance ratios between high-impedance and/or insulative states and low-impedance and/or conductive states.

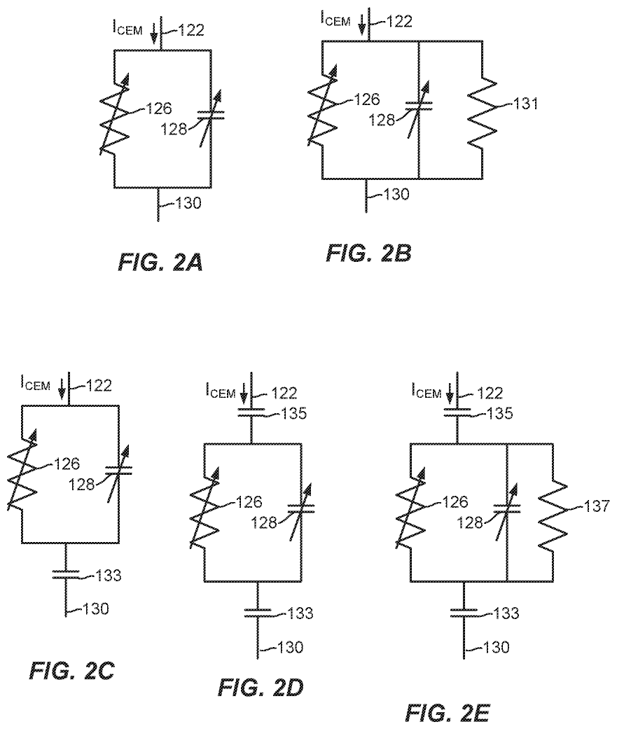

FIG. 2A is a schematic diagram of a CEM switch device and/or correlated electron switch (CES) device as shown FIG. 1B in which an impedance, represented by variable resistance 126 and variable capacitance 128, may be switchable between a low impedance and/or conductive state and a high impedance and/or insulative state in the absence of parasitic features and/or devices. As pointed out above, variable resistance 126 and variable capacitance 128 may be formed in a bulk CEM disposed between terminals, and such a bulk material may be etched to form a structure (e.g., “pillar” structure) to include exposed sidewalls of the thin film CEM formed between the metallic and/or electrode layers. FIGS. 2B through 2E are schematic diagrams of CES devices including parasitic features and/or devices formed in and/or in combination with bulk CEM from an etching process which may affect switching behavior of bulk material in the formed pillar structure. In this context, a “parasitic feature and/or device” as referred to herein means a feature and/or device formed in and/or in combination with a bulk CEM device that imparts undesired and/or unintended behavior to the bulk CEM device.

In FIG. 2B, for example, a parasitic feature and/or device may impart a resistance represented as resistor 131 in parallel with variable resistance 126 and variable capacitance 128. In FIG. 2C, for example, a parasitic feature and/or device may impart a capacitance represented as capacitor 133 in series with (parallel coupled) variable resistance 126 and variable capacitance 128. Similarly, FIG. 2D shows that parasitic features and/or devices may impart capacitances represented as capacitors 133 and 135 in series with (parallel coupled) variable resistance 126 and variable capacitance 128. Likewise, 2E shows that parasitic devices and/or features may impart capacitances represented as capacitors 133 and 135 in series with (parallel coupled) variable resistance 126 and variable capacitance 128, in addition to a resistance represented as resistor 137 in parallel with variable resistance 126 and variable capacitance 128. It should be understood, however, that these are merely examples of parasitic features and/or devices that may be present with a manufactured bulk material device, and that claimed subject matter is not limited in this respect.

According to an embodiment, and as described below, parasitic features and/or device may occur in the course of a process to form a CEM device. For example, parasitic features and/or devices may arise in or along sidewalls of an etched CEM thin film and/or in between different layers forming a CEM thin film. A sidewall of an etched CEM thin film may exhibit a lower resistance/resistivity (e.g., giving rise to a parasitic feature and/or device local to the sidewall) than a bulk resistance/resistivity of CEM material not local to sidewall regions. Here, for example, such a lower resistance and/or resistivity may arise during processing of a CEM device from a chemical reaction occurring at CEM local to a sidewall region (e.g., depletion of an extrinsic ligand and/or oxygen vacancies) and/or formation of a semiconducting material on sidewall regions (e.g., residue from a resputter of metal in an etching process). Such formation of a semiconducting material on sidewall regions may result in a short across bulk material of the CEM device (e.g., as represented by resistors 131 and 137 of FIGS. 2B and 2E, respectively). A growth of a non-conducting material or suppression of electron back-donation (e.g., making the material less conductive) in between layers forming a CEM thin film and/or bulk material may impart a parasitic feature and/or device such as, for example, an in series resistance and/or capacitance (e.g., as represented by capacitors 133 and 135 in FIGS. 2C, 2D and 2E). As discussed below, according to particular non-limiting embodiments, additional processes may be employed to remove and/or neutralize such parasitic features and/or devices introduced by process operations so as to restore and/or improve switching performance of a bulk CEM device.

It should be appreciated that non-volatile memory devices employing switching behavior other than switching in a bulk material (e.g., spin-transfer torque memory devices, MRAM, FeRAM and/or ReRAM) may address a presence of parasitic devices and/or features differently as such devices as such devices operate on different physical principles. As such, particular techniques employed to address a presence of parasitic features and/or devices in such other, different non-volatile memory devices may not be effective in addressing a presence of parasitic features and/or devices in a bulk CEM device. For example, a ReRAM device may be formed to address a presence of parasitic features and/or devices by using high voltage forming (e.g., so fusing the sidewall parasitic device or shorting the parasitic device in between the layers). As discussed below, particular non-limiting embodiments include additional processes specifically tailored to remove and/or neutralize parasitic features and/or devices introduced by operations to process a bulk CEM device so as to restore and/or improve switching performance of the bulk CEM device.

In certain embodiments, atomic layer deposition may be utilized to form and/or fabricate films comprising TMO materials (e.g., NiO materials, such as NiO:CO or NiO:NH₃), PTMO materials (e.g., BiO materials, such as BiO:CO) and/or PTMC materials. In this context, a “layer” as the term is used herein means a sheet and/or coating of material, which may be disposed on and/or over an underlying formation, such as a conductive or insulating substrate. For example, a layer deposited on an underlying substrate by way of an atomic layer deposition process may comprise a thickness dimension comparable to that of a single atom, which may comprise, for example, a fraction of an angstrom (e.g., 0.6 Å). However, in other embodiments, a layer may encompass a sheet and/or coating comprising a thickness dimension greater than that of a single atom depending, for example, on a process utilized to fabricate films comprising one or more CEM films. Additionally, a “layer” may be oriented horizontally (e.g., a “horizontal” layer), oriented vertically (e.g., a “vertical” layer), or may be positioned in any other orientation, such as diagonally, for example. In embodiments, a CEM film may comprise a sufficient number of layers, to permit electron back-donation during operation of a CEM device in a circuit environment, for example, to place such a CEM device in a low-impedance and/or conductive state. Also, during operation in a circuit environment, for example, electron back-donation may be reversed so as to give rise to a substantially dissimilar impedance state, such as a high-impedance and/or insulative state, for example.

Also in this context, a “substrate” as used herein means a structure comprising a surface that enables materials, such as materials having particular electrical properties (e.g., conductive properties, insulative properties, etc.) to be deposited, formed and/or placed on and/or over the substrate. For example, in a CEM-based device, a conductive substrate may operate in a manner similar to first conductor 160 to conduct an electrical current to a CEM film in contact with conductive substrate 160. In another example, a substrate may operate to insulate a CEM film to prohibit electrical current flow to and/or from the CEM film. In one possible example of an insulating substrate, a material such as silicon nitride (SiN) may be employed to insulate components of semiconductor structures. Further, an insulating substrate may comprise other silicon-based materials such as silicon-on-insulator (SOI) or silicon-on-sapphire (SOS) technology, doped and/or undoped semiconductors, epitaxial layers of silicon supported by a base semiconductor foundation, conventional metal oxide semiconductors (CMOS), e.g., a CMOS front end with a metal back end, and/or other semiconductor structures and/or technologies, including CES devices, for example. Accordingly, claimed subject matter is intended to embrace a wide variety of conductive and insulating substrates without limitation.

In particular embodiments, formation of CEM films on and/or over a substrate may utilize two or more precursors to deposit components of, for example, NiO:CO or NiO:NH₃, other metal oxide or metal (e.g., including other TMOs, PTMOs and/or PTMCs), or combination thereof, onto a conductive material such as a substrate. In an embodiment, layers of a CEM film may be deposited utilizing separate precursor molecules, AX and BY, according to expression (6A), below:

AX_{(gas)}+BY_{(gas)}=AB_{(solid)}+XY_{(gas)} (6A)

In an implementation, “A” of expression (6A) may correspond to a metal, metal compound, metal chalcogenide or metal oxide, or any combination thereof, such as a transition metal, transition metal compound, transition metal oxide, post transition metal, post transition metal oxide or post transition metal chalcogenide, or any combination thereof. In particular embodiments, such a transition metal, transition metal compound and/or transition metal oxide may comprise nickel, but may comprise other metals such as, for example, aluminum, cadmium, chromium, cobalt, copper, gold, iron, manganese, mercury, molybdenum, nickel palladium, rhenium, ruthenium, silver, tantalum, tin, titanium, vanadium, yttrium or zinc (which may be linked to an anion, such as oxygen or other types of ligands), or combinations thereof, although claimed subject matter is not limited in scope in this respect. In particular embodiments, compounds that comprise more than one transition metal oxide may also be utilized, such as yttrium titanate (YTiO₃).

In embodiments, “X” of expression (6A) may comprise a ligand, such as organic ligand, comprising am idinate (AMD), dicyclopentadienyl (Cp)₂, diethylcyclopentadienyl (EtCp)₂, Bis(2,2,6,6-tetramethylheptane-3,5-dionato) ((thd)₂), acetylacetonate (acac), bis(methylcyclopentadienyl) ((CH₃C₅H₄)₂), dimethylglyoximate (dmg)₂, 2-amino-pent-2-en-4-onato (apo)₂, (dmamb)₂ where dmamb=1-dimethylamino-2-methyl-2-butanolate, (dmamp)₂ where dmamp=1-dimethylamino-2-methyl-2-propanolate, Bis(pentamethylcyclopentadienyl) (C₅(CH₃)₅)₂ or carbonyl (CO)₄. Accordingly, in some embodiments, nickel-based precursor AX may comprise, for example, nickel am idinate (Ni(AMD)), nickel dicyclopentadienyl (Ni(Cp)₂), nickel diethylcyclopentadienyl (Ni(EtCp)₂), Bis(2,2,6,6-tetramethylheptane-3,5-dionato)Ni(II) (Ni(thd)₂), nickel acetylacetonate (Ni(acac)₂), bis(methylcyclopentadienyl)nickel (Ni(CH₃C₅H₄)₂, Nickel dimethylglyoximate (Ni(dmg)₂), nickel 2-amino-pent-2-en-4-onato (Ni(apo)₂), Ni(dmamb)₂ where dmamb=1-dimethylamino-2-methyl-2-butanolate, Ni(dmamp)₂ where dmamp=1-dimethylamino-2-methyl-2-propanolate, Bis(pentamethylcyclopentadienyl) nickel (Ni(C₅(CH₃)₅)₂ or nickel carbonyl (Ni(CO)₄), just to name a few examples.

In particular embodiments, layers of a metal oxide and/or metal chalcogenide film may be formed by application of a dopant operating as an electron back-donating species in addition to precursors AX and BY. An electron back-donating species, which may co-flow with precursor AX, may permit formation of electron back-donating compounds, substantially in accordance with expression (6B), below. In embodiments, a dopant species and/or a precursor to a dopant species, such as carbonyl (CO)₄, ammonia (NH₃), methane (CH₄), carbon monoxide (CO), or other precursors and/or dopant species may be utilized to provide electron back-donating ligands listed above. Thus, expression (6A) may be modified to include an additional dopant ligand comprising an electron back-donating material substantially in accordance with expression (6B), below:

AX_{(gas)}+(NH₃ or other ligand comprising nitrogen)+BY_{(gas)}=AB:NH_{3(solid)}+XY_{(gas)} (6B)

It should be noted that concentrations, such as atomic concentrations, of precursors, such as AX, BY, and NH₃ (or other ligand comprising nitrogen) of expressions (6A) and (6B) may be adjusted to give rise to a resulting atomic concentration of nitrogen-containing and/or carbon-containing dopant to permit electron back-donation in a fabricated CEM device. As referred to herein, the term “ligand atomic concentration” means an atomic concentration of atoms in a finished material that derive from a substitutional ligand (e.g., from application of a dopant). For example, in the case in which a substitutional ligand comprises CO, an atomic concentration of CO in percentage terms comprises a total number of carbon atoms that comprise a material film divided by a total number of atoms in the material film, multiplied by 100.0. In another example, for a case in which a substitutional ligand is NH₃, an atomic concentration of NH₃ comprises a total number of nitrogen atoms in a resulting material film divided by a total number of atoms in the resulting material film, multiplied by 100.0.

In particular embodiments, nitrogen- or carbon-containing dopants may comprise ammonia (NH₃), carbon monoxide (CO), or carbonyl (CO)₄ in an atomic concentration of between about 0.1% and about 20.0%. In particular embodiments, atomic concentrations of dopants, such as NH₃ and CO, may comprise a more limited range of atomic concentrations such as, for example, between about 1.0% and about 20.0%. However, claimed subject matter is not necessarily limited to the above-identified precursors and/or atomic concentrations. It should be noted that claimed subject matter is intended to embrace all such precursors and atomic concentrations of dopants utilized in atomic layer deposition, chemical vapor deposition, plasma chemical vapor deposition, sputter deposition, physical vapor deposition, hot wire chemical vapor deposition, laser enhanced chemical vapor deposition, laser enhanced atomic layer deposition, rapid thermal chemical vapor deposition, spin on deposition, gas cluster ion beam deposition, and/or the like, utilized in fabrication of CEM devices from metal oxide materials. In expressions (6A) and (6B), “BY” may comprise an oxidizer, such as water (H₂O), oxygen (O₂), ozone (O₃), plasma O₂, hydrogen peroxide (H₂O₂). In other embodiments, “BY” may comprise CO, O₂+(CH₄), nitric oxide (NO)+water (H₂O), an oxynitride, or carbon-containing gaseous oxidizing or oxynitridizing agent. In other embodiments, plasma may be used in combination with an oxidizer (BY) to form oxygen radicals (O*). Likewise, plasma may be used in combination with a dopant species to form an activated species to control dopant concentration in a CEM.

In particular embodiments, such as embodiments utilizing atomic layer deposition, a substrate, such as a conductive substrate, may be exposed to precursors, such as AX and BY of expression (6B), as well as dopants providing electron back-donation (such as ammonia or other ligands comprising metal-nitrogen bonds, including, for example, nickel-amides, nickel-im ides, nickel-am idinates, or combinations thereof) in a heated chamber, which may attain, for example, a temperature of approximately in the range of 20.0° C. to 1000.0° C., for example, or between temperatures approximately in the range of 20.0° C. and 500.0° C. in certain embodiments. In one particular embodiment, in which atomic layer deposition of NiO:NH₃, for example, is performed, chamber temperature ranges approximately in the range of 20.0° C. and 400.0° C. may be utilized. Following exposure to precursor gases (e.g., AX, BY, NH₃, or other ligand comprising nitrogen), such gases may be purged from the heated chamber for durations approximately in the range of 0.5 seconds to 180.0 seconds, for example. It should be noted, however, that these are merely examples of potentially suitable ranges of chamber temperature and/or time and claimed subject matter is not limited in this respect.

In certain embodiments, a single two-precursor cycle (e.g., AX and BY, as described with reference to expression (6A)) or a single three-precursor cycle (e.g., AX, NH₃, CH₄, or other ligand comprising nitrogen, carbon, or other electron back-donating dopant to provide a substitutional ligand and BY, as described with reference to expression (6B)) utilizing atomic layer deposition may bring about a layer of a metal oxide material film comprising a thickness dimension approximately in the range of 0.6 Å to 5.0 Å per cycle. Accordingly, in one embodiment, if an atomic layer deposition process is capable of depositing layers of a metal oxide material film comprising a thickness dimension of approximately 0.6 Å, 800-900 two-precursor cycles may be utilized to bring about a metal oxide material film comprising a thickness dimension of approximately 500.0 Å. It should be noted that atomic layer deposition may be utilized to form metal oxide material films having other thickness dimensions, such as thickness dimensions approximately in the range of about 15.0 Å to about 1500.0 Å, for example, and claimed subject matter is not limited in this respect.

In particular embodiments, responsive to one or more two-precursor cycles (e.g., AX and BY), or three-precursor cycles (AX, NH₃, CH₄, or other ligand comprising nitrogen, carbon or other back-donating dopant material and BY), of atomic layer deposition, a metal oxide material film may be exposed to elevated temperatures, which may, at least in part, enable formation of a CEM device from a metal oxide material film. Exposure of the metal oxide material film to an elevated temperature may additionally enable activation of a back-donating dopant derived from a substitutional ligand, such as in the form of carbon monoxide, carbonyl, or ammonia, responsive to repositioning of the dopant to metal oxide lattice structures of the CEM device film.

In particular embodiments, a CEM device manufactured in accordance with the above-described process may exhibit a “born on” property in which the device exhibits relatively low impedance (relatively high conductivity) immediately after fabrication of the device. Accordingly, if a CEM device is integrated into a larger electronics environment, for example, at initial activation a relatively small voltage applied to a CEM device may permit a relatively high current flow through the CEM device, as shown by region 104 of FIG. 1A. For example, as previously described herein, in at least one possible embodiment, a magnitude of Vᵣₑₛₑₜ may occur at a voltage approximately in the range of about 0.4 V to about 1.0 V, and a magnitude of Vₛₑₜ may occur at a voltage approximately in the range of about 1.0 V to about 2.0 V, for example. Accordingly, electrical switching voltages operating in a range of about 2.0 V, or less, may permit a memory circuit, for example, to change an impedance state of a CERAM device (e.g., to perform a “write operation” to a CERAM device) or detect an impedance state of a CERAM device (e.g., to perform a “read operation” on a CERAM device), for example. In embodiments, such relatively low voltage operation may reduce complexity, cost, and may provide other advantages over competing memory and/or switching device technologies.

In particular embodiments, two or more CEM devices may be formed within a particular layer of an integrated circuit at least in part by atomic layer deposition, chemical vapor deposition and/or physical vapor deposition of a material to be formed as CEM. In a further embodiment, one or more of a plurality of correlated electron switch devices of a first CEM and one or more of a plurality of correlated electron switch devices of a second CEM may be formed, at least in part, by a blanket deposition. Additionally, in an embodiment, first and second access devices may be positioned substantially adjacent to first and second CEM devices, respectively.

In a further embodiment, one or more of a plurality of CEM devices may be positioned within two or more levels of an integrated circuit at one or more intersections of electrically conductive metal layers of a first level and electrically conductive metal layers of a second level, which may be positioned over the first level of conductive metal layers. In this context a “metal layer” as the term is used herein, means a conductor capable of routing an electrical current from a first location to a second location of a layer of a multi-level CEM switching device. For example, a conductive metal layer may transport electrical current to or from an access device located at an intersection of a conductive metal layer of first level and a conductive metal layer of the second level. In certain embodiments, fabrication of a switching device formed from a multi-level CEM device, such as devices formed utilizing conductive metal layers positioned at multiple levels of a CEM switching device may be utilized in a CEM-based memory devices in which conductive metal layer positioned at multiple levels may facilitate an increase in bit line density, for example. Increases in bit line density may bring about more efficient and/or more highly integrated approaches toward controlling access to memory cells of CEM-based random access memory arrays, for example.

Also in this context, a “level” as the term is used herein, means a discrete surface, which a conductive metal layer may traverse, wherein such a discrete surface may be separated from other discrete surfaces immediately above and/or immediately below, by an insulating material. For example, as described herein, a conductive metal layer traversing a first level may be separated from a conductive metal layer traversing a second level by an insulating material, such as silicon nitride. In this context, a “multi-level” switching device, as the term is used herein, means a device to perform a switching function, such as from a high-impedance and/or insulative state to a low-impedance state, utilizing two or more of the above-described “levels.”

As described herein, in the course of deposition of one or more dopants on or over one or more layers of a first material, such as a transition metal, a transition metal oxide, a transition metal compound, transition metal alloy, a post transition metal, a post transition metal oxide, a post transition metal chalcogenide and/or post transition metal alloy, an amount of an applied dopant may be accurately controlled so as to control an atomic concentration of a resulting ligand in CEM. Additionally, by depositing one or more dopant layers on or over one or more layers of a first material, localized regions of CEM may comprise differing atomic concentrations of dopants so as to provide an approach toward tailoring and/or customizing a dopant concentration profile. Further, dopant concentration profiles within a CEM may be increased via adjusting annealing temperatures and/or annealing durations. In addition to the above-identified advantages, particular embodiments may provide an approach toward fabricating and/or forming three-dimensional structures, such as 3D structures utilized for NAND flash memory. However, claimed subject matter is not limited to the above-identified advantages.

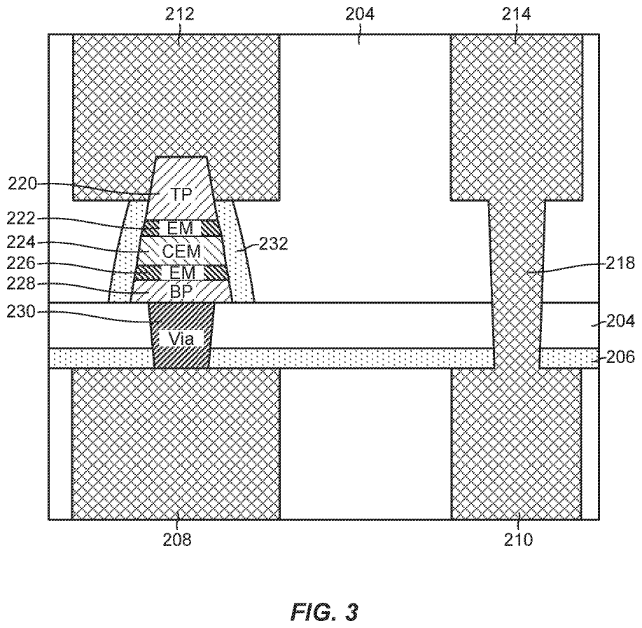

FIG. 3 is a cross-section of a switching device formed from a correlated electron material according to an embodiment. In particular embodiments, processes to form a switching device as shown in FIG. 3 may be performed during back-end-of-line integrated circuit fabrication processes (e.g., to form conducting structures following fabrication of transistor devices and/or other devices in a front-end-of-line integrated circuit fabrication), although in certain embodiments, features of a switching device may be formed during other stages of a circuit fabrication process, and claimed subject matter is not limited in this respect. Here, one or more layers of a correlated electron material (CEM) 224 may be disposed between a top plate layer 220 and a bottom plate layer 228. Bottom plate layer 228 and top plate layer 220 may comprise a conductive material such as TaN. Top plate layer 220 may conduct a signal between metal layer 212 and layers of CEM 224 while bottom plate 228 and metal via 230 may conduct a signal between metal layer 208 and layers of CEM 224. According to an embodiment, layers of CEM 224 may be formed as a correlated electron switch behaving as illustrated in FIG. 1A as described above. In an embodiment, a pulse signal may be applied to top plate layer 220 to affect a voltage and current density in layers of CEM 224 to effect a write operation to change an impedance state of layers of CEM 224 between a low impedance and/or conductive state and a high impedance and/or insulative state, as illustrated in in FIG. 1A. For example, a pulse applied to top layer 220 may bring about a voltage Vₛₑₜ across layers of CEM 224 and a current density Jₛₑₜ in at least a portion of layers of CEM 224 provide to place layers of CEM 224 in a low impedance and/or conductive state. Similarly, a pulse signal applied to top plate layer 220 may bring about a voltage Vᵣₑₛₑₜ across layers of CEM 224 and a current density Jᵣₑₛₑₜ≥J_{comp} in at least a portion of layers of CEM 224 provide to place layers of CEM 224 in a high impedance and/or insulative state.

In the particular illustrated embodiment, a switching device comprising layers of CEM 224, bottom plate layer 228 and top plate layer 220 may be formed on a substrate 204 comprising a dielectric material, which is disposed over a capping layer 206. In certain embodiments, substrate 204 may comprise a thickness of between about 1.0 nm and about 50.0 nm, just as an example, and comprise a material such as a fluorosilicate glass having a relatively low relative dielectric constant, such as between about 2.0 and about 4.2, for example. However, in other embodiments, substrate 204 may comprise a material different from fluorosilicate glass, such as, for example, fluorine-doped silicon dioxide, carbon-doped silicon dioxide, spin-on organic polymer dielectric, and so forth.

Substrate 204 may be disposed on capping layer 206. Capping layer 206 may operate to reduce and/or preclude moisture from entering from metal layer 208 and may comprise a material such as silicon nitride, silicon carbon nitride or aluminum nitride, or any combination thereof, and claimed subject matter is not limited to any particular type of capping material. In particular embodiments, capping layer 206 may comprise a thickness of between about 0.5 nm and about 20.0 nm, for example, although claimed subject matter is intended to embrace capping layers comprising a variety of thicknesses, virtually without limitation.

Following formation of capping layer 206 and substrate 204 on or over metal layer 208, via 230 may be formed, such as by way of an etching process followed by a metal filling process. In particular embodiments, such an etching process to form via 230 may comprise a reactive ion etching and/or sputter etching process, just to name a couple of examples. Following completion of an etching process, via 230 may be formed by filling an etched volume with a suitable material such as tungsten, for example, which may provide an electrically conductive path between metal layer 208 and, for example, bottom plate layer 228. It should be noted, however, that via 230 may comprise a conductive material other than tungsten, and claimed subject matter is not limited in this respect.

Sealing layer 232 may comprise an atomic or molecular concentration of at least 50.0% silicon nitride (SiN), silicon oxynitride (SiON), silicon carbon nitride (SiCN), silicon carbide (SiC) or aluminum nitride (AlN), or any combination thereof, for example. In particular embodiments, sealing layer 232 may comprise a material having a relative dielectric constant of, for example, between about 3.0 and about 10.0. However, in other embodiments, sealing layer 232 may comprise a material having a dielectric constant within the range of about 2.0 to about 20.0, and claimed subject matter is not limited in this respect. Sealing layer 232 may comprise a thickness of, for example, between about 2.0 nm, and about 100.0 nm, although claimed subject matter is intended to embrace any useful thickness of sealing layer 232.

In embodiments, insulative filling material 204 may comprise any suitable dielectric material having a dielectric constant of, for example, between about 2.0 and about 4.5. In certain embodiments, insulative filling material 204 may comprise silicon dioxide (SiO₂) having a dielectric constant of, for example, about 3.9. However, claimed subject matter is intended to embrace a variety of insulative filling material materials, such as SiO₂, silicon nitride (SiN), titanium dioxide (TiO₂), and so forth, virtually without limitation.

According to an embodiment, layers of CEM 224 may be formed from a metal oxide such as, for example, NiO and/or other metal oxides such as, for example, HfOx, YOx, TiOx and/or TaOx, just to name a few. Also as discussed above, layers of CEM 224 may be formed from a PTMO and/or PTMC. Metal oxide or metal chalcogenide making up layers of CEM 224 may also be doped with a carbon-containing dopant such as, for example, CO to a particular atomic concentration. In alternative implementations, metal oxide making up layers of CEM 224 may be doped with other dopants such as NO (e.g., activated with an ambient O₂/N₂ gas mixture) to enable desired switching behavior for a CEM device.

In the presently illustrated embodiment, a layer of electrode material 222 may be disposed between top plate layer 220 and layers of CEM 224, and a layer of electrode material 226 may be disposed between bottom plate layer 228 and layers of CEM 224. In an embodiment, layers of electrode material 222 and 226 may comprise a noble metal such as, for example, silver, gold, platinum, rhodium, iridium, palladium, ruthenium, and/or rhenium. In an implementation, layers of electrode material 222 and 226 formed from a noble metal may inhibit and/or prevent escape of oxygen, hydrogen, CO or CO₂ from layers of CEM 224 into top plate layer 220 and/or bottom plate layer 228. Additionally, a noble metal forming electrode layers 222 and 226 may provide a sufficient work function to enable application of a pulse signal to layers of CEM 224 to affect a change in impedance state such as in a write operation.

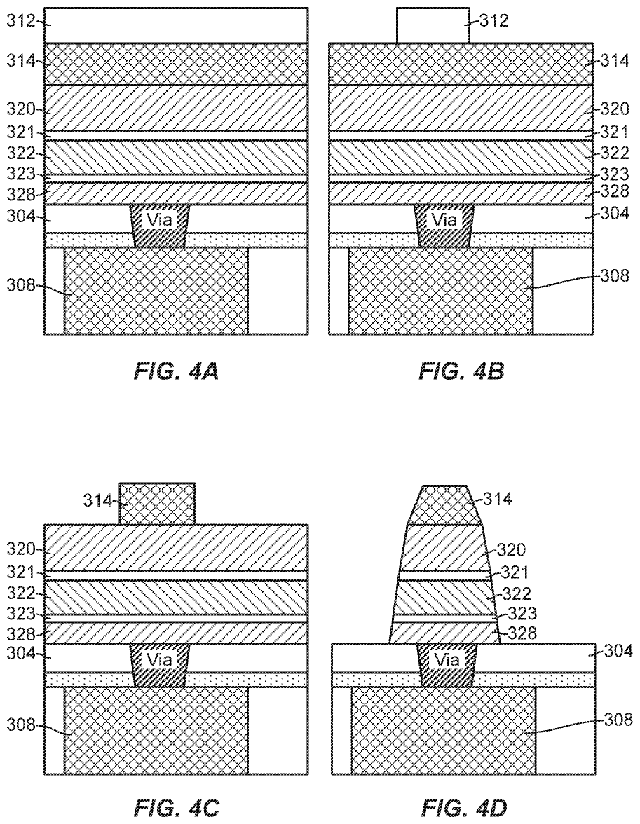

FIGS. 4A through 4D are cross-sectional diagrams illustrating stages in forming a switching device comprising a correlated electron material from deposited layers of material, such as a switching device shown in FIG. 3, according to an embodiment. A lithographic film layer 312 may be disposed over a hard mask layer 314 (e.g., formed from an oxide or TiN). In a transition from FIG. 4A to FIG. 4B, portions of lithographic film layer may be removed according to a pattern to expose portions of hard mask layer 314. Exposed portions of hard mask layer 314 may then be removed as shown in FIG. 4C. According to an embodiment, a dry etch process may be applied to the structure shown in FIG. 4C by, for example, applying an ion beam etch, plasma sputter etch or other anisotropic etching process, or a combination thereof, which may occur in an etching chamber. Such a dry etch process applied to the structures shown in FIG. 4C may remove portions of top plate layer 320, electrode layer 321, CEM layers 322, electrode layer 323 and bottom plate layer 328 to provide a remaining structure having a switch device disposed under hard mask 314. Additionally, such a dry etch process may stop at a surface of substrate 304.

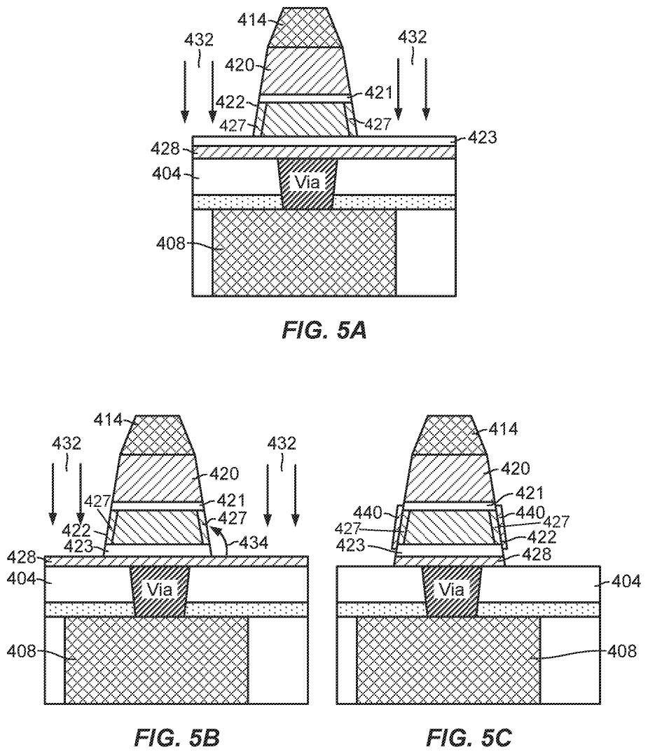

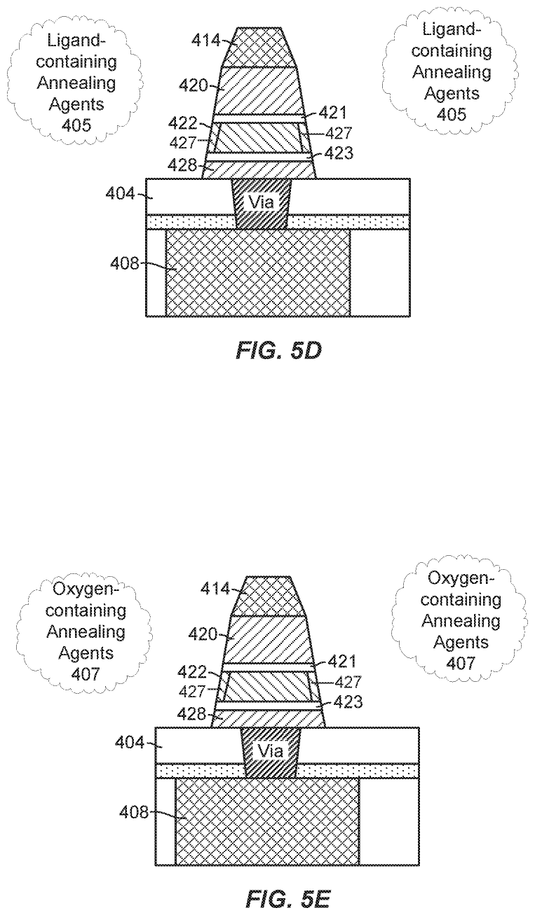

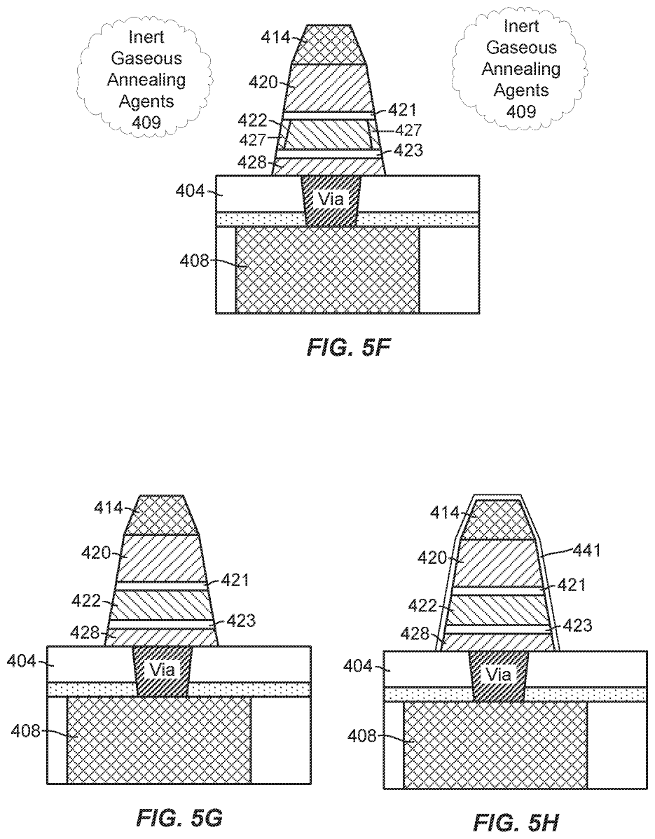

As illustrated in FIGS. 5A and 5B, a process of dry etching to remove portions of electrode layer 323 in FIG. 4D to form a pillar structure may result in formation of one or more parasitic feature and/or devices affecting switching performance of a bulk material disposed between electrode material layers 421 and 423. For example, such parasitic features and/or devices formed by etching shown in FIGS. 5A and 5B may comprise one or more parasitic devices and/or features shown in FIGS. 2B through 2E, for example.

As shown in FIG. 5A, a dry etch process 432 may remove portions of top plate layer 420, electrode layer 421, CEM layers 422, electrode layer 423 and bottom plate layer 428 to provide a remaining structure comprising a switch device disposed under hard mask 414. According to an embodiment, application of dry etch process 432 may affect a composition of regions 427 of CEM 422 which are local to sidewalls of the formed structure. For example, dry etch process 432 may affect a composition of regions 427 of CEM layers 422 so as to introduce a presence of one or more parasitic features and/or devices in and/or in combination with a bulk switching portion of CEM 422.

In particular embodiments, exposure of sidewall regions to a dry etching process involving high-energy ions may alter an ability of regions 427 to be switched between a high-impedance/insulative state and a low-impedance/conductive state, and/or may introduce a presence of parasitic features and/or devices. In particular embodiments, such alteration may arise responsive to effects of high-energy ions giving rise to dislocations of ligands (e.g., CO dopants) within a lattice structure of a metal oxide or metal chalcogenide (of regions 427), such as NiO. In particular embodiments, collisions between high-energy ions in the course of dry etch process 432 and relatively low atomic-weight ligands (e.g., CO dopants) may bring about dislocation and/or vaporization of ligand species (e.g., C and/or O of a CO ligand). Dry etch process 432 may bring about additional alterations of chemical and/or electrical properties of regions 427 local to sidewalls, and claimed subject matter is not limited in this respect.

Responsive to exposure of sidewalls local to regions 427 to high-energy ions during a dry etching process, a significant portion of an electric current flowing between conductive overlay electrode material layers 421 and 423 may be routed through one or more of regions 427. For example, affected regions 427 may impart a parasitic feature and/or device such as a resistance as modeled by resistors 131 (FIG. 2B) and/or 137 (FIG. 2E). Accordingly, other portions of CEM layers 422 may become less involved in impedance switching operations, such as switching from a high-impedance/insulative state to a low-impedance/conductive state.

As pointed out above, application of dopant to a bulk material (e.g., in the formation of CEM layers 422) may introduce an “extrinsic ligand” and/or “substitutional ligand” such as carbon, nitrogen and/or CO capable of binding with molecules of the host material to substitute for intrinsic ligands if, for example, oxygen vacancies occur in molecules of a host material. In an implementation, exposure of sidewall regions to a dry etching process involving high-energy ions (such as dry etch process 432) may alter a concentration and/or presence of oxygen vacancies in regions 427, which may introduce parasitic features and/or devices in CEM layers 422. For example, an increase in a concentration of oxygen vacancies in regions 427 arising from a dry etching process involving high-energy ions may, in effect, act as an N-type dopant to undercut an effectiveness of a P-type dopant to bring about reversible backdonation. In a specific example in which a ratio of metal ions to oxygen may be about 1.1, for example, an atomic concentration of an extrinsic ligand (e.g., CO) may be less than 1.0%. Oxygen vacancies that are not occupied by an extrinsic ligand may then act as an N-type dopant. Additionally, an increase in oxygen vacancies may introduce an increase in a concentration of metal-to-metal bonding, thereby introducing one or more parasitic features and/or devices. In an embodiment, a parasitic device may manifest in a as a presence of a conduction mechanism in CEM layers 422 (e.g., such as a feature that is parallel with CEM layers 422) other than while CEM layers 422 are in a conductive and/or low impedance state.

As shown in FIGS. 5B and 5C, a metallic residue 440 may form on a sidewall from a resputterring of material forming electrode layer 423. In applying dry etch process 432 to remove portions of electrode layer 423, at least a part a removed portion of electrode layer 423 may be resputtered as metal particles 434 to collect as sidewall residue 440 as shown in FIG. 5C. Metallic sidewall residue 440 may then at least in part introduce a short circuit across CEM layers 422 and/or a resistance to act as a parasitic feature and/or device (e.g., modeled as resistor 131 (FIG. 2B) and/or resistor 137 (FIG. 2E)).

One particular technique for removing and/or neutralizing parasitic features and/or devices arising from resputtered metals collecting as a sidewall residue 440 as shown in FIG. 5C is to apply an oxidation treatment following an etching stage. By oxidizing sidewall residue 440, sidewall residue 440 may become inert and/or insulative metal oxide, thereby removing a short introduced by metal of sidewall residue 440. As pointed out above, electrode layer 423 may comprise a noble metal disposed between a bottom plate layer (e.g., bottom plate layer 228) and CEM layers (e.g., CEM layers 224). If, in the course of dry etching process 432, such noble metal electrode material deposits as metallic sidewall residue 440, such deposited noble metal electrode material may not be sufficiently oxidized using an oxidation treatment so as to render the deposited noble metal electrode material inert and/or insulative metal oxide. Additionally, such noble metal electrode material deposits as metallic sidewall residue 440 may not be easily removed (e.g., using a wet clean process).

According to an embodiment, electrode material of electrode layer 423 disposed between CEM layers 422 and bottom plate layer 428 may be replaced with an electrode material comprising metal nitride that may provide a sufficient oxygen barrier between CEM layers 422 and bottom plate layer 428. For example, such a metal nitride may provide an inert layer to inhibit and/or prevent oxygen from escaping a metal oxide forming CEM layers 422. Such a metal nitride material of electrode layer 423 may comprise, for example, one or more of TiN, TaN, MgN, BN or AlN, just to provide a few examples of metal nitrides that may provide a sufficient oxygen barrier. In an embodiment, such an electrode material may be sufficiently rich in nitrogen to be effective in providing an oxygen barrier such as to have an atomic concentration of nitrogen of at least 50% and/or substantially no metal-to-metal bonds.

According to an embodiment, metallic sidewall residue 440 formed from a resputterring of an electrode material comprising a metal nitride may readily oxidize so as to become more insulative by, for example, an in-situ oxidation treatment (e.g., 02 plasma and/or 02 thermal anneal). Alternatively, application of a reactive ion etch cleaning process with a Cl₂-based chemical may remove resputtered metal residue (e.g., from Ti, Ta, Mg, B or Al). In yet another alternative implementation, application of a solvent (e.g., a room temperature SC1 solvent, H₂O, acetone, isopropyl alcohol, nitric acid, diluted hydrofluoric acid (DHF), diluted HCl or DHF in combination with nitric acid) in a wet clean process may remove at least a portion of sidewall residue (e.g., Ni, Ti, Ta, Mg, B or Al) formed by a resputterring of a metal nitride.

In an alternative to application of an oxidation process or chemical removal process to a metal sidewall residue (e.g., from resputterring of electrode material formed from TiN, TaN, MgN, BN or AlN), electrode material may be etched using an reactive ion etch (RIE) process. For example, as illustrated in FIG. 5A, portions of hard mask layer 414, top plate layer 420, electrode layer 421 and layers of CEM 422 may be removed by application of an ion beam etch (IBE) process which terminates and/or stops after removal of portions of layers of CEM 422 and prior to etch of electrode layer 423 and bottom plate layer 428. Portions of bottom plate 428 and electrode layer 423 (e.g., including a metal nitride electrode material such as TiN, TaN, MgN, BN or AlN) may be removed by application of a reactive ion etch (RIE) process to provide a device as shown in FIG. 5D. Here, such an RIE process applied to a metal nitride electrode material may create a volatile metal biproduct metal that may reduce resputterring of metal to form as sidewall residue. Additionally, any resulting residue from application of an RIE process to a metal nitride electrode material may be addressed by application of an oxidation process or chemical removal process to a metal sidewall residue 440 as described above.

FIGS. 5D through 5F illustrate example treatments and/or processes to remove and/or neutralize presence of parasitic features and/or devices from regions 427 caused by etching according to alternative embodiments. As shown in FIGS. 5D, 5E and 5F, one or more processes of annealing in an annealing chamber (not shown) in a presence of gaseous annealing agents (e.g., ligand-containing annealing agents 405, oxygen-containing annealing agents 407 and/or inert gaseous annealing agents 409) may at least in part neutralize and/or remove parasitic features and/or devices introduced to regions 427 by dry etch process 432 discussed above. In particular implementations, processes shown in FIGS. 5D, 5E and 5F are not interdependent in that one or any combination of processes shown in FIGS. 5D, 5E and 5F may be performed. Additionally, while processes shown in FIGS. 5D, 5E and 5F are presented in a particular order, it should be understood that any combination of processes shown in FIGS. 5D, 5E and 5F may be performed in any order. Additionally, one or any combination of processes shown in FIGS. 5D, 5E and 5F may be performed in combination with, or without processes discussed above to remove and/or oxidize a metal residue forming on a sidewall (e.g., residue 440).

In one particular implementation, ligand-containing annealing agents 405, oxygen-containing annealing agents 407 and/or inert gaseous containing annealing agents 409 may be maintained at an annealing temperature of between about 40.0° C. and about 400.0° C. for a particular duration (e.g., 10 seconds to 10 hours). Alternatively, annealing agents 405, oxygen-containing annealing agents 407 and/or inert gaseous containing annealing agents 409 may be applied in combination with rapid thermal annealing (RTA) processes such as by maintaining a temperature of up to 1000° C. for 10 nsec to 24 hours. Such annealing processes may, for example, restore atomic concentrations of dopants or oxygen vacancies within affected regions 427 sidewall regions, for example, as well as to align grain boundaries and/or arrange dopant molecules or atoms within lattice structures in affected regions to be consistent with a bulk CEM of CEM layers 422.

In one example, one or more of ligand-containing annealing agents 405 may, at least for one or more intervals of an annealing process, comprise a high concentration, such as a controlled atomic concentration of a carbon-containing gaseous material of up to 90% or more. In an embodiment, such a controlled atomic concentration of a carbon-containing gaseous material may be varied to achieve a desired resulting atomic concentration of carbon-based ligand (or other extrinsic ligand) in regions 427. In one embodiment, a carbon-containing gaseous material may be combined with an inert gas in controlled concentrations to achieve such a desired resulting concentration of carbon-based ligand in regions 427. An interval of an annealing process involving ligand-containing annealing agents 405 comprising a high concentration of carbon-containing gaseous material may be maintained for a duration of between about 10 seconds and about 120.0 minutes at a partial pressure of between about 1.33 Pa to about 100.0 kPa. Suitable carbon-containing molecules that constitute one or more of ligand-containing annealing agents 405 may include carbon monoxide (CO), carbon dioxide (CO₂), and/or the like. In particular embodiments, during one or more initial intervals of an annealing process, use of a carbon-containing gaseous annealing agent in ligand-containing annealing agents may operate to deposit a significant amount of carbon into exposed portions of regions 427. For example, for layers of CEM 422 (e.g., comprising a nickel-based CEM), such an exposure of regions 427 may bring about conversion of Ni to Ni—C or Ni—CO. Such deposition of carbon in an early portion of an annealing process may allow deposited carbon to diffuse deeper into regions 427 during subsequent portions of an annealing process (e.g., as illustrated in FIGS. 5E and 5F). As such, deposition of carbon in one or more early intervals of an annealing process in FIG. 5D may enable additional restorative outcomes (e.g., to remove and/or neutralize one or more parasitic features and/or devices), and claimed subject matter is not limited in this respect.

In an embodiment, regions 427 may be exposed to one or more oxygen-containing annealing agents 407 as shown in FIG. 5E. Oxygen-containing annealing agents 407 may comprise, for example, a gaseous oxygen-containing agent, such as oxygen (O₂) or ozone (O3+), for example. In particular embodiments, a gaseous annealing agent 407 may comprise an atomic concentration of up to 90.0% or more of an oxygen-containing agent maintained at an annealing temperature (as discussed above) and a partial pressure of between about 1.33 Pa to about 100.0 kPa for a duration of between about 10 seconds and about 120.0 minutes, which may permit oxygen to diffuse into exposed portions of regions 427. An atomic concentration of such an oxygen-containing annealing agent may be controlled so as to achieve a desired concentration of oxygen vacancies in regions 427, for example. Oxygen atoms diffusing through exposed portions of regions 427 may be capable of forming, for example, ionic bonds with carbon atoms (e.g., diffused through exposed portions of regions 427 from exposure to ligand-containing agents 405 in FIG. 5D prior to annealing of exposed sidewall regions in a presence of oxygen-containing annealing agents 407). Bonding of oxygen atoms with previously diffused carbon atoms may at least partially restore CO dopant concentration, such as via conversion of Ni—C to NiO:CO, within regions 427. In particular embodiments, regions 427 may additionally be exposed to a remote plasma source, which may energize and dissociate oxygen-containing gases (e.g., previously diffused through exposed portions of regions 427). Such dissociation may generate, for example, reactive oxygen so as to permit oxygen radicals to form, for example, Ni—C═O.

According to an embodiment, exposure of regions 427 to oxygen-containing annealing agents 407 may, at least in part, reduce a presence of oxygen vacancies arising from etching process 432 (e.g., undercutting an effect of P-type dopant to promote backdonation) to thereby at least partially remove and/or neutralize parasitic features and/or devices introduced by an increase in a concentration of oxygen vacancies. In particular implementations, application of oxygen-containing annealing agents 407 to reduce a concentration of oxygen vacancies in regions 427 may be controlled so as to inhibit, avoid and/or minimize reaction of ambient oxygen with CO dopants to provide gaseous CO₂ that may escape CEM layers 422. For example, an oxidation process, while inhibiting, avoiding and/or minimizing reaction of ambient oxygen with CO dopants, may be achieved by controlling chamber process parameters such as, for example, annealing temperature, atomic concentration of O₂ or chamber pressure, just to provide a few examples of chamber process parameters that may be varied to remove oxygen vacancies while inhibiting, avoiding and/or minimizing reaction of ambient oxygen with CO dopants.

In an embodiment, regions 427 may be exposed to inert gaseous annealing agents 409 as shown in FIG. 5F. Inert gaseous annealing agents 409 may comprise, for example, a relatively inert gaseous agent, such as argon (Ar), helium (He), nitrogen (N₂), or similar and in any combination, relatively nonreactive gaseous agent in an atomic concentration of up to 90% or more. For example, regions 427 may be exposed to inert gaseous annealing agents 409 comprising a controlled atomic concentration of a relatively inert gaseous agent maintained at an annealing temperature as discussed above and a partial pressure of between about 1.33 Pa to about 100.0 kPa for a duration of between about 10 seconds and about 120.0 minutes so as to bring about additional diffusion of dopants, such as CO, for example, as well as bringing about repair of microstructural defects within regions 427. In particular embodiments, two or more annealing processes (e.g., as illustrated in FIGS. 5D, 5E and 5F) may occur within a single chamber, thereby allowing annealing processes to be performed at relatively constant and/or controlled partial pressures of gaseous annealing agents.

In certain embodiments, in addition to or in place of being exposed to one or more annealing agents such as ligand-containing annealing agents 405, oxygen-containing annealing agents 407 and/or inert gaseous annealing agents 409, regions 427 may be at least partially restored via application of liquid materials such as, for example, application of carbon-rich liquids, oxygen-rich liquids, argon- and/or nitrogen-rich liquids, just to name a few. In a possible embodiment, one or more of such liquids may be applied following a dry etch process (e.g., such as dry etch process 432) via spin-on deposition followed by exposure of sidewall regions to an elevated temperature, such as a temperature of between about 100.0° C. and about 500.0° C., for example.

According to an embodiment, following processes to remove and/or neutralize parasitic features and/or devices (e.g., as discussed above with reference to FIGS. 5C, 5D, 5E and/or 5F), an encapsulation layer 441 may be formed over the device shown in FIG. 5G to provide a device shown in FIG. 5H. In particular implementations, encapsulation layer 441 may comprise any suitable material such as, for example, silicon nitride, silicon carbide, silicon carbon nitride or aluminum nitride, or any combination thereof.

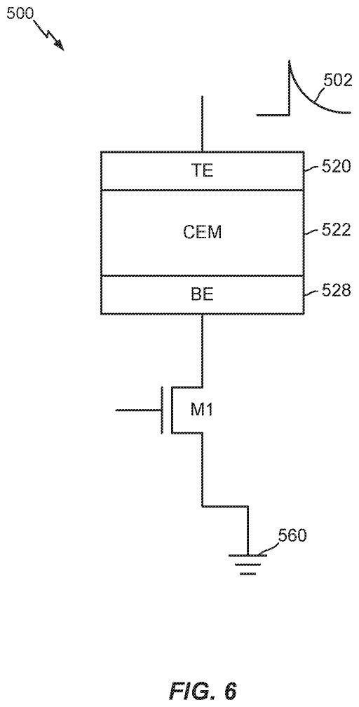

FIG. 6 is a schematic diagram of a circuit comprising one or more layers of CEM 522 disposed between a top electrode (TE) 520 and a bottom electrode (BE) 528 to provide a switching device according to an embodiment. In an implementation, circuit 500 may comprise schematic diagram of an equivalent of switch device shown in FIG. 5G or 5H, for example, in which TE 520 is formed from electrode material layer 421 and BE 528 is formed from electrode material layer 423. To place CEM layers 522 in a particular impedance state, transistor M1 may be closed to couple BE 528 to a reference node 560 while a pulse signal 502 is applied to TE 520. For example, application of pulse signal 502 while transistor M1 is closed may bring about a voltage Vₛₑₜ across CEM layers 522 and a current density Jₛₑₜ in at least a portion of CEM layers 522 to place CEM layers 522 in a low impedance and/or conductive state. Likewise, application of pulse signal 502 while transistor M1 is closed may bring about a voltage Vᵣₑₛₑₜ across CEM layers 522 and a current density Jᵣₑₛₑₜ≥J_{comp} in at least a portion of CEM layers 522 to place CEM layers 522 in a high impedance and/or insulative state.

Pulse signal 502 may comprise a positive polarity relative to BE 528. In the particular implementation illustrated in FIG. 6, application of pulse signal 502 may not affect a bulk switch behavior in CEM layers 522 uniformly between TE 520 and BE 528. For example, a resulting current density in layers of CEM 522 from application of pulse signal 502 may be higher closer to a boundary with TE 520 than closer to a boundary with BE 528. As such, bulk switching behavior in CEM layers 522 may be more pronounced closer to such a boundary with TE 520 than BE 528. In some embodiments, for example, bulk switching behavior in CEM layers 522 closer to a boundary with BE 528 may be negligible. While bulk switching behavior in layers of CEM 522 closer to a boundary with BE 528 may be limited, bulk switching behavior occurring closer to a boundary with TE 520 may be sufficient to implement an operational switching device.

As pointed out above in particular embodiments described above, electrode material provided in TE 520 at a boundary with CEM layers 522 (e.g., electrode material to form electrode material layer 421) may comprise a noble metal to provide a sufficiently high work function to facilitate bulk switching in CEM layers 522 closer to a boundary with TE 520 (e.g., enabling implementation of an operational switching device). As such, bulk switching behavior is to occur in CEM layers 522 close to a boundary with TE 520 responsive to electrons passing through boundary between TE 520 and CEM layers 522. In this context, “work function” of an element and/or material means work and/or energy to enable removal an electron from a solid surface of the element and/or material to a point in a vacuum immediately outside the solid surface. Here “immediately” means that the final electron position is far from the surface on the atomic scale, but still too close to the solid to be influenced by ambient electric fields in the vacuum. For example, a noble metal such as Ir or Au may have a work function of 5.0 eV. If bulk switching in device 500 is to be limited to application of pulse signal 502 at TE 520 and not from application of a pulse signal at BE 528, a work function of electrode material in BE 528 at a boundary with CEM layers 522 (e.g., in electrode material layer 423) need not have as high a work function as electrode material provided in TE 520 at a boundary with CEM layers 522. As such, electrode material in BE 528 at a boundary with CEM layers 522 need not be formed from a noble metal if switching is not to occur from application of a pulse signal at BE 528. As pointed out above, electrode material in BE 528 at a boundary with CEM layers 522 may instead comprise a metal nitride that is sufficiently rich in nitrogen to provide an inert layer to inhibit and/or prevent oxygen from escaping a metal oxide forming CEM layers 522.

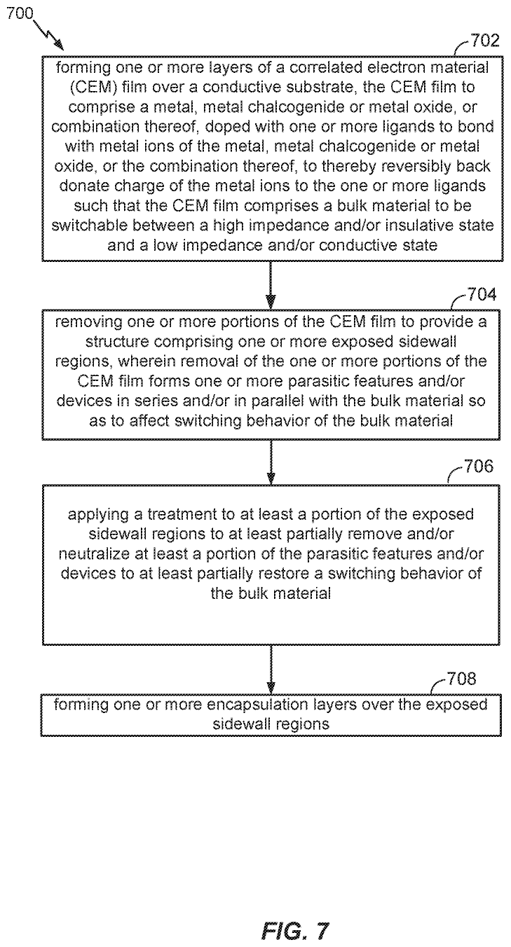

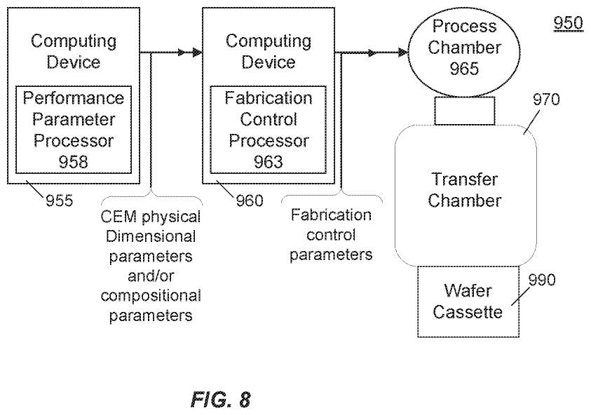

FIG. 7 is a flow diagram of a process 700 to form a switch device according to an embodiment. According to an embodiment, block 702 may comprise formation of one or more layers of CEM as layers of CEM 422. In a particular implementation, block 702 may further comprise formation of layers of CEM 422 over a bottom electrode comprising a metal nitride as discussed above. Such a bottom electrode may be formed prior to formation of one or more layers of CEM at block 702 by, for example, deposition of a metal nitride material (e.g., material for electrode layer 423) being sufficiently rich in nitrogen (e.g., having an atomic concentration of nitrogen of at least 50%) to provide barrier to prevent escape of oxygen from a metal oxide material. As pointed out above, such a metal nitride material may comprise or more of TiN, TaN, MgN, BN or AlN. In one particular implementation, a bottom electrode layer comprising a metal nitride material may be formed by depositing a metal nitride material over a substrate of conductive material such as TaN, for example. In an implementation, such metal nitride deposited over a substrate of conductive material such as TaN may provide an electrode material between one or more layers of a metal oxide and such a conductive material comprising TaN capable of preventing escape of oxygen from the metal oxide.

To form one or more layers of CEM, block 702 may comprise depositing a material such as one or more layers of NiO and/or other metal oxides such as, for example, HfOx, YOx, TiOx and/or TaOx, PTMOs or PTMCs, just to name a few examples. To bring about switching behavior, such deposited layers of metal oxide may also be doped with a carbon-containing dopant such as, for example, CO, and/or a nitrogen-containing dopant such as, for example, NO, to a particular atomic concentration. Block 702 may also comprise annealing deposited material activate applied dopants to impart backdonation properties.

Following, formation of one or more layers of CEM at block 702, an electrode layer may be formed over the formed one or more layers of CEM by deposition of one or more layers of a noble metal such as, for example, silver, gold, platinum, rhodium, iridium, palladium, ruthenium, and/or rhenium. Layers formed over one or more layers of CEM at block 702 may provide, for example, an electrode material (e.g., as electrode layer 421) between layers of CEM and a top plate layer (e.g., top plate layer 420) comprising a conductive metal such as TaN as discussed above. As pointed out above, such an electrode material comprising a noble metal may provide an oxygen barrier to prevent escape of oxygen in layers of CEM formed at block 702 while also providing a sufficiently high work function enabling bulk switching capabilities responsive to a pulse signal applied to a top electrode.

As pointed out above, layers may be formed at block 702 using any one of several suitable deposition process techniques such as, for example, atomic layer deposition, chemical vapor deposition, plasma chemical vapor deposition, sputter deposition, physical vapor deposition, hot wire chemical vapor deposition, laser enhanced chemical vapor deposition, laser enhanced atomic layer deposition, rapid thermal chemical vapor deposition, spin on deposition, gas cluster ion beam deposition, and/or the like, utilized in fabrication of CEM devices from metal oxide and/or metal chalcogenide materials. It should be noted, however, layers may be formed at block 702 may be formed utilizing other, different processes, and that claimed subject matter is not intended to be limited in this respect.

Following block 702, a resulting device may be further processed at block 704 to remove one or more portions of a CEM film formed at block 702 to provide a structure (e.g., a pillar structure having sidewalls). For example, block 704 may comprise for example, etching (e.g., via etch process 432) to form a switch device. As pointed out above, an etching process applied at block 702 may introduce one or more parasitic features and/or devices to a CEM film in a structure formed by block 704.

Block 706 comprises application of one or more processes to remove and/or neutralize at least a portion of parasitic features and/or devices, such as parasitic features and/or devices introduced by an etching process at block 704. In an embodiment in which electrode material deposited to form a bottom electrode layer (e.g., to form electrode layer 423) of a material comprising a nitrogen-rich metal nitride, formation of a resputterred metal as a residue to a sidewall (e.g., sidewall residue 440) of a CEM device may be reduced, removed and/or mitigated using techniques discussed above. Here, block 706 may include a process such as, for example, application of an RIE process to remove metal nitride electrode material, an oxidation process to make metal sidewall material more insulative and/or chemical process to remove metal sidewall residue as discussed above. Block 706 may also comprise application of one or more annealing processes in the presence of a gaseous annealing agent such as, for example, annealing in a presence of ligand-containing annealing agents 405 (FIG. 5D), oxygen-containing annealing agents 407 (FIG. 5E) and/or inert gaseous annealing agents 409 (FIG. 5F), just to provide a few examples.

FIG. 8 is a schematic of a system for forming CEM devices according to an embodiment 950. According to an embodiment, processes carried out as described above with reference to FIGS. 4A through 4D and 5A through 5H may be carried out in process chamber 965 at least in part under control of computing devices 955 and/or 960. For example, in a particular implementation, one or more aspects of blocks 702, 704, 706 and/or 708 (FIG. 7) may be performed within process chamber 965 at least in part under control of computing devices 955 and/or 960. According to an embodiment, layers of material to form a switching device as illustrated in FIGS. 4A through 4D and FIGS. 5A through 5H (e.g., hard mask layers 314 and 414, top plate layers 320 and 420, electrode layers, 321, 323, 421 and 423, layers of CEM 322 and 422, bottom plate layers 328 and 428, and encapsulation layer 441) may be formed in process chamber 965 using any one of several suitable deposition processes such as, for example, atomic layer deposition, chemical vapor deposition, plasma chemical vapor deposition, sputter deposition, physical vapor deposition, hot wire chemical vapor deposition, laser enhanced chemical vapor deposition, laser enhanced atomic layer deposition, rapid thermal chemical vapor deposition, spin on deposition, gas cluster ion beam deposition, and/or the like, utilized in fabrication of CEM devices from metal oxide materials. It should be noted, however, that particular layers in devices shown in FIG. 4A through DD and 5A through 5H may be formed utilizing other, different processes, and that claimed subject matter is not intended to be limited in this respect.

Computing device 955 may comprise performance parameter processor 958, which may operate to specify physical dimensional and/or compositional parameters of one or more CEM devices to be formed at a stage of a fabrication process. In certain embodiments, processor 958 may use or access a database of particular device operational performance parameters that may be possible for devices formed at differing stages of a wafer fabrication process. In embodiments, such operational performance parameters may be linked to, for example, CEM physical dimensional parameters and/or compositional parameters. In particular embodiments, a database, accessible to performance parameter processor 958, may comprise a physical dimensional and/or compositional parameters of transistors, access devices, logic devices, for example, that may be formed at a front-end-of-line stage of a wafer fabrication process. A database accessible to processor 958 may additionally comprise physical dimensional and/or compositional parameters of switching devices, through-substrate vias, interposers, and a variety of additional other devices that may be formed at middle-of-line, the back-end-of-line, and 2.5D/3D system integration stages of a wafer fabrication process. For example, if a particular current versus applied voltage for a memory access device has been specified, performance parameter processor 958 may specify particular physical dimensional parameters and/or compositional parameters of one or more CEM devices that exhibit the specified current versus applied voltage profile.

In embodiment 950, computing device 960 may obtain CEM physical dimensional parameters and/or compositional parameters and may generate particular device settings and other control parameters to be utilized by process chamber 965, transfer chamber 970, and wafer cassette 990. For example, responsive to computing device 960 obtaining one or more CEM physical dimensional parameters and/or compositional parameters, fabrication control processor 963 may operate to specify fabrication control parameters, such as dopant precursors to be utilized by process chamber 965, to form CEM devices that meet specified application performance parameters. Other fabrication control parameters generated by fabrication control processor 963 may include CEM material selections, dopant concentration profiles utilized during deposition processes, chamber pressure, annealing temperatures, exposure durations, and a variety of additional settings utilized by process chamber 965, and claimed subject matter is not limited in this respect. In embodiments, after fabrication of one or more wafers comprising CEM devices, transfer chamber may transport fabricated wafers to wafer cassette 990 for singulation and/or other postprocessing of fabricated CEM wafers. In embodiments, process chamber 965 may be utilized to form CEM devices having a depth of between 2.0 nm and 200.0 nm. Accordingly, process chamber 965 may be utilized to form front-end-of-line CEM devices, middle-of-line CEM devices, back-end-of-line devices, and CEM devices utilized in 2.5D/3D system integration of wafers, and claimed subject matter is not limited in this respect.

In embodiments, computing devices 955 and 960 may comprise a memory or storage device, which may include primary and secondary memories, which may communicate with processors 958 and 960 utilizing, for example, an internal bus structure, for example. Computing devices 955 and 960 may represent one or more sources of analog, uncompressed digital, lossless compressed digital, and/or lossy compressed digital formats for content of various types, such as video, imaging, text, audio, etc. in the form physical states and/or signals, for example. Computing device 955 may communicate with one another by way of a connection, such as an internet connection, for example. Although computing devices 955 and 960 of FIG. 8—show only a few components, claimed subject matter is not limited to computing devices having only these components as other implementations may include alternative arrangements that may comprise additional components or fewer components, such as components that function differently while achieving similar results. It is not intended that claimed subject matter be limited in scope to illustrative examples.

In the preceding description, in a particular context of usage, such as a situation in which tangible components (and/or similarly, tangible materials) are being discussed, a distinction exists between being “on” and being “over.” As an example, deposition of a substance “on” a substrate refers to a deposition involving direct physical and tangible contact without an intermediary, such as an intermediary substance (e.g., an intermediary substance formed during an intervening process operation), between the substance deposited and the substrate in this latter example; nonetheless, deposition “over” a substrate, while understood to potentially include deposition “on” a substrate (since being “on” may also accurately be described as being “over”), is understood to include a situation in which one or more intermediaries, such as one or more intermediary substances, are present between the substance deposited and the substrate so that the substance deposited is not necessarily in direct physical and tangible contact with the substrate.

A similar distinction is made in an appropriate particular context of usage, such as in which tangible materials and/or tangible components are discussed, between being “beneath” and being “under.” While “beneath,” in such a particular context of usage, is intended to necessarily imply physical and tangible contact (similar to “on,” as just described), “under” potentially includes a situation in which there is direct physical and tangible contact but does not necessarily imply direct physical and tangible contact, such as if one or more intermediaries, such as one or more intermediary substances, are present. Thus, “on” is understood to mean “immediately over” and “beneath” is understood to mean “immediately under.”

It is likewise appreciated that terms such as “over” and “under” are understood in a similar manner as the terms “up,” “down,” “top,” “bottom,” and so on, previously mentioned. These terms may be used to facilitate discussion but are not intended to necessarily restrict scope of claimed subject matter. For example, the term “over,” as an example, is not meant to suggest that claim scope is limited to only situations in which an embodiment is right side up, such as in comparison with the embodiment being upside down, for example. An example includes a flip chip, as one illustration, in which, for example, orientation at various times (e.g., during fabrication) may not necessarily correspond to orientation of a final product. Thus, if an object, as an example, is within applicable claim scope in a particular orientation, such as upside down, as one example, likewise, it is intended that the latter also be interpreted to be included within applicable claim scope in another orientation, such as right side up, again, as an example, and vice-versa, even if applicable literal claim language has the potential to be interpreted otherwise. Of course, again, as always has been the case in the specification of a patent application, particular context of description and/or usage provides helpful guidance regarding reasonable inferences to be drawn.

Unless otherwise indicated, in the context of the present disclosure, the term “or” if used to associate a list, such as A, B, or C, is intended to mean A, B, and C, here used in the inclusive sense, as well as A, B, or C, here used in the exclusive sense. With this understanding, “and” is used in the inclusive sense and intended to mean A, B, and C; whereas “and/or” can be used in an abundance of caution to make clear that all of the foregoing meanings are intended, although such usage is not required. In addition, the term “one or more” and/or similar terms is used to describe any feature, structure, characteristic, and/or the like in the singular, “and/or” is also used to describe a plurality and/or some other combination of features, structures, characteristics, and/or the like. Furthermore, the terms “first,” “second,” “third,” and the like are used to distinguish different aspects, such as different components, as one example, rather than supplying a numerical limit or suggesting a particular order, unless expressly indicated otherwise. Likewise, the term “based on” and/or similar terms are understood as not necessarily intending to convey an exhaustive list of factors, but to allow for existence of additional factors not necessarily expressly described.

Furthermore, it is intended, for a situation that relates to implementation of claimed subject matter and is subject to testing, measurement, and/or specification regarding degree, to be understood in the following manner. As an example, in a given situation, assume a value of a physical property is to be measured. If alternatively reasonable approaches to testing, measurement, and/or specification regarding degree, at least with respect to the property, continuing with the example, is reasonably likely to occur to one of ordinary skill, at least for implementation purposes, claimed subject matter is intended to cover those alternatively reasonable approaches unless otherwise expressly indicated. As an example, if a plot of measurements over a region is produced and implementation of claimed subject matter refers to employing a measurement of slope over the region, but a variety of reasonable and alternative techniques to estimate the slope over that region exist, claimed subject matter is intended to cover those reasonable alternative techniques, even if those reasonable alternative techniques do not provide identical values, identical measurements or identical results, unless otherwise expressly indicated.

It is further noted that the terms “type” and/or “like,” if used, such as with a feature, structure, characteristic, and/or the like, using “optical” or “electrical” as simple examples, means at least partially of and/or relating to the feature, structure, characteristic, and/or the like in such a way that presence of minor variations, even variations that might otherwise not be considered fully consistent with the feature, structure, characteristic, and/or the like, do not in general prevent the feature, structure, characteristic, and/or the like from being of a “type” and/or being “like,” (such as being an “optical-type” or being “optical-like,” for example) if the minor variations are sufficiently minor so that the feature, structure, characteristic, and/or the like would still be considered to be predominantly present with such variations also present. Thus, continuing with this example, the terms optical-type and/or optical-like properties are necessarily intended to include optical properties. Likewise, the terms electrical-type and/or electrical-like properties, as another example, are necessarily intended to include electrical properties. It should be noted that the specification of the present disclosure merely provides one or more illustrative examples and claimed subject matter is intended to not be limited to one or more illustrative examples; however, again, as has always been the case with respect to the specification of a patent application, particular context of description and/or usage provides helpful guidance regarding reasonable inferences to be drawn.

In the preceding description, various aspects of claimed subject matter have been described. For purposes of explanation, specifics, such as amounts, systems, and/or configurations, as examples, were set forth. In other instances, well-known features were omitted and/or simplified so as not to obscure claimed subject matter. While certain features have been illustrated and/or described herein, many modifications, substitutions, changes, and/or equivalents will occur to those skilled in the art. It is, therefore, to be understood that the appended claims are intended to cover all modifications and/or changes as fall within claimed subject matter.

What is claimed is:

1. A method of constructing a switching device, comprising:
forming one or more layers of a correlated electron material (CEM) film over a conductive substrate, the CEM film to comprise a metal, metal chalcogenide or metal oxide, or combination thereof, doped with one or more ligands to bond with metal ions of the metal, metal chalcogenide or metal oxide, or the combination thereof, to thereby reversibly back donate charge of the metal ions to the one or more ligands such that the CEM film comprises a bulk material to be switchable between a high impedance and/or insulative state and a low impedance and/or conductive state;
removing one or more portions of the CEM film to provide a structure comprising one or more exposed sidewall regions, wherein removal of the one or more portions of the CEM film forms one or more parasitic features and/or devices in series and/or in parallel with the bulk material so as to affect switching behavior of the bulk material; and
applying a treatment to at least a portion of the exposed sidewall regions to at least partially remove and/or neutralize at least a portion of the parasitic features and/or devices to at least partially restore a switching behavior of the bulk material; and
forming one or more encapsulation layers over the exposed sidewall regions.

2. The method of claim 1, wherein the one or more parasitic features and/or devices comprise portions of the CEM film local to the sidewall regions to have an atomic concentration of oxygen vacancies that is different from a concentration of oxygen vacancies at a center of region of the structure; and wherein applying the treatment to the exposed sidewall regions comprises applying one or more treatments to affect the atomic concentration of oxygen vacancies local to the sidewall regions.

3. The method of claim 2, wherein applying the treatment to the exposed sidewall regions to affect the concentration of oxygen vacancies local to the sidewall regions further comprises:
annealing the exposed sidewall regions in a presence of ambient O₂, N₂ or plasma, or a combination thereof.

4. The method of claim 1, wherein applying the treatment to the at least a portion of the exposed sidewall further comprises annealing the exposed sidewall regions in a presence of a selected concentration of one or more gases while maintaining an ambient temperature of between 40 C.° and 400 C.° for between 10 sec and 10 hours.

5. The method of claim 1, wherein applying the treatment to the exposed sidewall regions to at least partially remove and/or neutralize the at least a portion the parasitic devices further comprises annealing the exposed sidewall regions in the presence of a selected concentration of one or more gases while maintaining an ambient temperature of up to 1000 C.° for between 10 nano seconds and 24 hours.

6. The method of claim 1, wherein removing the one or more portions of the CEM film to provide the structure comprising exposed sidewall regions comprises etching portions of the CEM film, wherein the one or more parasitic features and/or devices comprise residue formed on the exposed sidewall from a resputter of material from the etching, and wherein applying the treatment to the at least a portion of the exposed sidewall regions to at least partially remove and/or neutralize at least a portion of the parasitic features and/or devices to at least partially restore switching behavior of the bulk material comprises removing at least a portion of the residue.

7. The method of claim 1, wherein applying the treatment to the exposed sidewall regions further comprises:
applying a wet clean process to at least partially remove the residue from the exposed sidewall regions.

8. The method of claim 7, wherein applying the wet clean process comprises applying an isopropyl alcohol, acetone or H₂O, hydrofluoric acid, SC1, nitric acid, or a combination thereof, to the exposed sidewall regions.

9. The method of claim 1, wherein removing the one or more portions of the CEM film to provide a structure comprises performing a dry etch of at least a portion of the CEM film.

10. The method of claim 8, wherein the dry etch comprises an ion beam etch or plasma sputter etch, or a combination thereof.

11. The method of claim 1, wherein at least one of the formed one or more parasitic features and/or devices comprises one or more portions of the CEM film local to the sidewall having a depletion of at least a portion of the one or more ligands, and wherein:
applying the treatment to the at least a portion of the exposed sidewall regions comprises applying a dopant to the at least a portion of the exposed sidewall region.

12. The method of claim 11, wherein applying the dopant to the at least a portion of the exposed sidewall region comprises annealing the exposed sidewall region in an environment comprising a controlled atomic concentration of gaseous carbon dioxide to achieve a desired concentration of a carbon ligand in the at least a portion of the exposed sidewall region, a controlled atomic concentration of a gaseous oxygen-containing agent to achieve a desired concentration of oxygen vacancies in the at least a portion of the exposed sidewall region or a controlled atomic concentration of an inert gas to enable diffusion of dopants and/or repair micro-structural defects in the exposed sidewall region, or a combination thereof.

13. The method of claim 12, wherein the inert gas comprises argon, nitrogen or helium, or a combination thereof.

14. The method of claim 1, wherein applying the treatment to the at least a portion of the exposed sidewall region comprises annealing the exposed sidewall region in an environment comprising an atomic concentration of gaseous oxygen selected to achieve a desired concentration of oxygen vacancies in the at least a portion of the exposed sidewall region.

15. The method of claim 14, wherein the annealing of the exposed sidewall region in the environment comprising an atomic concentration of gaseous oxygen comprises generating reactive oxygen radicals utilizing a remote plasma source.

16. The method of claim 1, wherein applying the treatment to the at least a portion of the exposed sidewall region comprises annealing the exposed sidewall region in an environment comprising an atomic concentration of argon, nitrogen or helium, or a combination thereof, to enable diffusion of dopants and/or repair micro-structural defects in the exposed sidewall region.

17. The method of claim 1, wherein the encapsulation layer comprises silicon nitride, silicon oxy-nitride, silicon carbide, silicon carbon nitride, aluminum nitride or aluminum oxide, or any combination thereof.

18. An apparatus comprising:
one or more processing chambers; and
one or more processors to provide one or more control signals to the one or more processing chambers to:
form one or more layers of a correlated electron material (CEM) film over a conductive substrate, the CEM film to comprise a metal, metal chalcogenide or metal oxide, or combination thereof, doped with one or more ligands to bond with metal ions of the metal, metal chalcogenide or metal oxide, or the combination thereof, to thereby reversibly back donate charge of the metal ions to the one or more ligands such that the CEM film comprises a bulk material to be switchable between a high impedance and/or insulative state and a low impedance and/or conductive state;
remove one or more portions of the CEM film to provide a structure comprising one or more exposed sidewall regions, wherein removal of the one or more portions of the CEM film forms one or more parasitic features and/or devices in series and/or in parallel with the bulk material so as to affect switching behavior of the bulk material; and
apply a treatment to at least a portion of the exposed sidewall regions to at least partially remove and/or neutralize at least a portion of the parasitic features and/or devices to at least partially restore a switching behavior of the bulk material; and
form one or more encapsulation layers over the exposed sidewall regions.

19. A device comprising:
one or more layers of a correlated electron material (CEM) film disposed over a conductive substrate, the CEM film to comprise a metal, a metal chalcogenide or metal oxide, or combination thereof, doped with one or more ligands such that the CEM film comprises a bulk material to be switchable between a high impedance and/or insulative state and a low impedance and/or conductive state, the one or more layers of the CEM film to have a structure including sidewall regions; and
one or more encapsulation layers disposed over sidewall regions of the one or more layers of the CEM film,
wherein an atomic concentration of the ligand at the sidewall regions and a center region of the structure is substantially uniform or an atomic concentration of oxygen vacancies at the sidewall regions and the center region of the structure is substantially uniform, or a combination thereof.

20. The device of claim 19, and further comprising an electrode material disposed between the one or more layers of the CEM film and the conductive substrate, and wherein an oxidized residue of the electrode material is disposed between the sidewall regions and the one or more encapsulation layers.
